(19) United States
(12) Patent Application Publication
(10) Pub. No.: US 2014/0197399 A1
(43) Pub. Date: Jul. 17, 2014

(54) ORGANIC ELECTROLUMINESCENT ELEMENT, LIGHTING DEVICE AND DISPLAY DEVICE

(71) Applicant: Hideo Taka, Tokyo (JP)

(72) Inventor: Hideo Taka, Tokyo (JP)

(73) Assignee: Konica Minolta, Inc., Tokyo (JP)

(21) Appl. No.: 14/238,886

(22) PCT Filed: Aug. 21, 2012
(86) PCT No.: PCT/JP2012/071022

§ 371 Date: Feb. 14, 2014

(30) Foreign Application Priority Data
Aug. 23, 2011 (JP) 2011-171304

(51) Int. Cl. H01L 51/50; H01L 27/32

(52) U.S. Cl. CPC H01L 51/5012; H01L 27/3244
USPC 257/40

(57) ABSTRACT

Provided are: an organic electroluminescent element that has high charge injection/transport performance and a long service life, with little change in driving voltage over time; a manufacturing method; a lighting device; and a display device. An organic EL element according to the present invention comprises a plurality of organic compound layers that include a hole transport layer, a light emitting layer, and an electron transport layer. This organic EL element is characterized in that (1) the hole transport layer and the electron transport layer are each adjacent to the light emitting layer, and the light emitting layer contains a phosphorescent light-emitting organic metal complex compound; (2) the Tg of a hole transport material having the highest constituent ratio among the constituents of the hole transport layer is higher that the Tg of a host material having the highest constituent ration among the constituents of the light emitting layer; and (3) the Tg of an electron transport material having the highest constituents ratio among the constituents of the electron transport layer is higher than the Tg of the host material having the highest constituent ration among the constituents of the light emitting layer.

### FIELD OF THE INVENTION

The present invention relates to an organic electroluminescent element, and a lighting device and a display device that use the organic electroluminescent element(s).

### BACKGROUND ART

An organic electroluminescent element (hereinafter arbitrary abbreviated as an organic EL element) is a thin all-solid-state element composed of electrodes and films made from organic materials and having a thickness of only about 0.1 μm. Such an organic EL element emits light with a relatively low voltage of about 2 to 20 V, and this technique is therefore expected for use in future flat displays and lighting devices.

An organic EL element utilizing phosphorescence emission, which has been recently found, can achieve efficiency of light emission of about four times larger in principle than that of a conventional element utilizing fluorescence emission. Thus, research and development regarding layer configurations as well as development of materials for such an element utilizing phosphorescence emission have been extensively conducted all over the world (see Patent Document 1, Non-Patent Documents 1 to 3, for example).

This technique therefore has a high potentiality. An organic EL device utilizing phosphorescence emission is largely different in that it is an important technical challenge for efficiency and life of the element to control positions of light emission centers, especially to stabilize light emission by causing recombining in a light-emitting layer.

Given the above, a multi-layered element including individual functions, especially including a hole-transporting layer on and adjacent to an anode side of a light-emitting layer and an electron-transporting layer on ad adjacent to a cathode side of the light-emitting layer has been used (see Patent Document 2, for example).

However, change with time in charge injecting and transporting properties, especially change in voltages in constant current driving is not satisfactory. Thus, further improvements are needed.

### PRIOR ART DOCUMENT

### Patent Document

Patent Document 1: U.S. Pat. No. 6,097,147
Patent Document 2: Japanese Patent Application Laid-Open Publication No. 2005-112765

### Non-Patent Document

Non-Patent Document 1: M. A. Baldo, et al., Nature, Vol. 395, pp. 151-154 (1998)
Non-Patent Document 2: M. A. Baldo, et al., Nature, Vol. 403, No. 17, pp. 750-753 (2000)
Non-Patent Document 3: S. Lamansky et al., J. Am. Chem. Soc., Vol. 123, p. 4304 (2001)

### SUMMARY OF THE INVENTION

### Problem to be Solved by the Invention

The present invention is made in view of the above problems and situations to provide an organic electroluminescent element, a lighting device and a display device with high electron injecting and transporting properties, high external extraction quantum efficiencies, less changes with time in driving voltage in constant current driving and long lives.

### Means for Solving Problem

The above problems are solved by the following configurations.

1. An organic electroluminescent element including a plurality of organic compound layers including a hole-transporting layer, a light-emitting layer and an electron-transporting layer, the plurality of the organic compound layers being provided between an anode and a cathode, wherein

(1) the hole-transporting layer and the electron-transporting layer are each adjacent to the light-emitting layer,
(2) Tg(HT)>Tg(EM) where a glass transition temperature (Tg) of a hole-transporting material constituting the hole-transporting layer in a highest constitution ratio among a hole-transporting material(s) constituting the hole-transporting layer is defined as Tg(HT) and a glass transition temperature (Tg) of a host material constituting the light-emitting layer in a highest constitution ratio among a host material(s) constituting the light-emitting layer is defined as Tg(EM),
(3) Tg(ET)>Tg(EM) where a glass transition temperature (Tg) of an electron-transporting material constituting the electron-transporting layer in a highest constitution ratio among an electron-transporting material(s) constituting the electron-transporting layer is defined as Tg(HT) and the glass transition temperature (Tg) of the host material constituting the light-emitting layer in the highest constitution ratio among the host material(s) constituting the light-emitting layer is defined as Tg(EM), and
(4) a phosphorescent organic metal complex compound is contained as a material constituting the light-emitting layer.

2. The organic electroluminescent element of the above 1, wherein

the glass transition temperature Tg of the host material contained in the light-emitting layer ranges from 70 to 130° C.

3. The organic electroluminescent element of the above 1 or 2, wherein

the hole-transporting material contained in the hole-transporting layer is a polymer.

4. The organic electroluminescent element of any one of the above 1 to 3, wherein

the electron-transporting material contained in the electron-transporting layer is a polymer.

5. The organic electroluminescent element of the above 1 or 2, wherein

both of the hole-transporting material contained in the hole-transporting layer and the electron-transporting material contained in the electron-transporting layer are polymers.

6. The organic electroluminescent element of any one of the above 1 to 6, wherein

at least one of the phosphorescent organic metal complex compound(s) is a compound represented by a following formula (1):

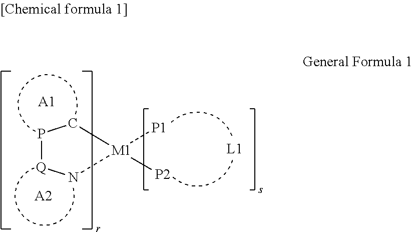

wherein P and Q each represent a carbon atom or a nitrogen atom; A1 represents a group of atoms forming an aromatic hydrocarbon ring or an aromatic hetereo ring together with P—C; A2 represents a group of atoms forming an aromatic hetero ring together with Q-N; P1-L1-P2 represents a bidentate ligand; P1 and P2 each independently represent a carbon atom, a nitrogen atom or an oxygen atom; L1 represents a group of atoms forming the bidentate ligand together with P1 and P2; r represents an integer from 1 to 3; s represents an integer from 0 to 2; r plus equals 2 or 3; and M represents a metal element of Group 8 to 10 of the periodic table.

7. The organic electroluminescent element of any one of the above 1 to 6, wherein

the organic electroluminescent element emits white light.

8. A lighting device including the organic electroluminescent element of any one of the above 1 to 6.

9. A display device including the organic electroluminescent element of any one of the above 1 to 6.

### Effect of the Invention

The present invention provides an organic electroluminescent element, a lighting device and a display device with high external extraction quantum efficiencies, less changes with time in driving voltage in constant current driving and long lives.

### BRIEF DESCRIPTION OF DRAWING

FIG. 1 This is a schematic diagram illustrating a display device using organic electroluminescent elements.

FIG. 2 This is a schematic diagram illustrating a display unit A.

FIG. 3 This is a schematic diagram illustrating a pixel.

FIG. 4 This is a schematic diagram of a full-color display device of a passive matrix system.

FIG. 5 This is a schematic diagram illustrating a lighting device.

FIG. 6 This is a schematic diagram illustrating a lighting device.

FIG. 7 This is a schematic diagram illustrating a configuration of a full-color display device using the organic electroluminescent elements.

### EMBODIMENT FOR CARRYING OUT THE INVENTION

Hereinafter, embodiments for carrying out the present invention will be descried in detail, but the present invention is not limited thereto.

Constituent elements according to the present invention will now be each described one another.

<<Constituent Layer and Organic Compound Layer of Organic EL Element>>

Constituent layers and organic compound layers of the organic EL element of the present invention will now be described. Preferred examples of layer configurations of the organic EL element of the present invention are listed below, but the present invention is not limited thereto.

(i) Anode/Hole-transporting layer/Light-emitting layer/Electron-transporting layer/Cathode

(ii) Anode/Hole-transporting layer/Light-emitting layer/Electron-transporting layer/Cathode buffer layer/Cathode

(iii) Anode/Anode buffer layer/Hole-transporting layer/Light-emitting layer/Electron-transporting layer/Cathode f¥buffer layer/Cathode

<<Organic Compound Layer (Also Referred to as Organic Layer)>>

Organic compound layers of the present invention will now be described. The organic EL element of the present invention preferably include a plurality of organic compound layers. Examples of the organic compound layers include the hole-transporting layer, the light-emitting layer and the electron-transporting layer listed above, and further include other layers including organic compounds constituting other constituent layers such as a hole-injecting layer and an electron-injecting layer.

If organic compounds are used for forming an anode buffer layer, a cathode buffer layer and the like, these layers are also the organic compound layers.

If the organic EL element of the present invention include a blue light-emitting layer, a green light-emitting layer and/or a red light-emitting layer, these layers are preferably monochromatic light-emitting layers emitting light of a maximum wavelength in the range of 430 to 480 nm, 510 to 550 nm and 600 to 640 nm, respectively. A preferable display device includes these layers.

In the organic EL element, at least these three light-emitting layers may be laminated into a white light-emitting layer. Furthermore, non-light-emitting intermediate layer(s) may be disposed between these light-emitting layers.

The organic EL element of the present invention is preferably a white light-emitting layer. A preferable lighting device includes these layers.

Constituent layers of the organic EL element of the present invention will now be described.

<<Light-Emitting Layer>>

The light-emitting layer of the present invention emits light by recombination of electrons and holes injected from electrodes or an electron-transporting layer and electron hole-transporting layer. The light emission sites may be inside the light-emitting layer or may be the interface between the light-emitting layer and its adjacent layer.

The total thickness of the light-emitting layer is not particularly limited, but is preferably controlled within a range of 2 nm to 5 μm, more preferably 2 to 200 nm, and most preferably 10 to 20 nm from the viewpoints of homogeneity of the film, prevention of application of unnecessarily high voltage for light emission and an improvement in stability of color(s) of light(s) based on the driving current.

The light-emitting layer can be produced by forming a thin film using a light-emitting dopant(s) or host material(s) described later by a known film forming method such as vacuum deposition, spin coating, casting, LB method or ink jetting.

The light-emitting layer of the organic EL element of the present invention includes a host material(s) (also referred to as a host compound(s)) and a phosphorescent organic metal complex compound(s) as a light-emitting material (s) (also referred to as a light-emitting dopant(s)). The light-emitting layer may further include a hole-transporting material(s) and an electron-transporting material(s) described later.

(Host Material)

The host compound used in the present invention will now be described. In the present invention, the host compound is defined as a compound that is contained in the light-emitting layer in a mass ratio of 20% or more based on the compound(s) contained in the layer and that has a phosphorescence quantum yield of phosphorescence emission of less than 0.1, and preferably less than 0.01 at room temperature (25° C.).

The host compound may be used together with any other known host compound(s) in combination. Otherwise, multiple host compounds may be used. The use of multiple host compounds facilitates the control of the transportation of charge and thus increases the efficiency of the organic EL element. The use of multiple light-emitting dopants described later allows mixing of different light and thereby allows the generation of any intended light color.

The conventionally known host compound that can be used in combination is preferably a compound having electron hole-transporting properties and electron-transporting properties, preventing the shift of light emission to the longer wavelength side, having a high glass transition temperature (Tg), and being in the following relation with a hole-transporting material(s) constituting the hole-transporting layer and an electron-transporting material(s) constituting the electron-transporting layer.

(1) the hole-transporting layer and the electron-transporting layer are each adjacent to the light-emitting layer

(2) Tg(HT)>Tg(EM) where a glass transition temperature (Tg) of a hole-transporting material constituting the hole-transporting layer in the highest constitution ratio among a hole-transporting material(s) constituting the hole-transporting layer is defined as Tg(HT) and a glass transition temperature (Tg) of a host-material constituting the light-emitting layer in the highest constitution ratio among a host material(s) constituting the light-emitting layer is defined as Tg(EM)

(3) Tg(ET)>Tg(EM) where a glass transition temperature (Tg) of an electron-transporting material constituting the electron-transporting layer in the highest constitution ratio among an electron-transporting material(s) constituting the electron-transporting layer is defined as Tg(HT) and the glass transition temperature (Tg) of the host material constituting the light-emitting layer in the highest constitution ratio among the host material(s) constituting the light-emitting layer is defined as Tg(EM)

More preferably, the glass transition temperature of the host material contained in the light-emitting layer in the highest constitution ratio ranges from 70 to 130° C.

A material contained in the hole-transporting layer, the electron-transporting layer or the light-emitting layer in the highest constitution ratio can be understood as determining Tg (glass transition temperature) of each layer. Thus, Tgs of the materials contained in the these layers in the highest constitution ratios are described as Tg of the hole-transporting layer, Tg of the light-emitting layer, and Tg of the electron-transporting layer for convenience.

The organic electroluminescent element with high charge injecting and transporting properties, high light emission efficiency, a less change with time in driving voltage and a long life can be obtained when the hole-transporting layer and the electron-transporting layer are each adjacent to the light-emitting layer including a phosphorescent organic metal complex compound(s) and Tg (HT) of the hole-transporting layer and Tg (ET) of the electron transporting layer. This can be explained as follows.

In the organic compound layers of the organic EL element, when Tg is lower, reorientation energy is relatively high. Carriers are then easy to be trapped and thus mobility of the carriers is smaller.

On the other hand, whrn Tg is high, reorientation energy is relatively small. Carriers are then difficult to be trapped and their mobility is high.

Therefore, when the hole-transporting layer and the electron transporting layer sandwich and are adjacent to the light-emitting layer having a Tg smaller than those of the hole-transporting layer and the electron-transporting layer, it is expected that carriers are trapped in the light-emitting layer and efficiency of light emission is increased.

When a plurality of hole-transporting layers and electron-transporting layers are provided, the hole-transporting layer and the electron-transporting layer in the context of the present invention are the layers each adjacent to the light-emitting layer.

To make such a configuration, materials descried later are selected so as to obtain the above-described relation. As for the light-emitting layer, the host material contained therein in the highest constitution ratio preferably has a glass transition temperature ranging from 70 to 130° C. for providing a light-emitting layer having a not-so-high glass transition temperature and providing the hole-transporting layer and the electron-transporting layer each having a glass transition temperature higher than that of the light-emitting layer.

The hole-transporting layer and the electron-transporting layer preferably include polymers so as to have Tgs higher than that of the light-emitting layer. Preferably, the hole-transporting material and the electron-transporting material are polymers.

Both of the hole-transporting layer and the electron-transporting layer are composed of polymers. In the present invention, the polymer is a compound having a weight-average molecular weight of 10000 or more. A method for measuring the weight-average molecular weight is described below.

(Measurement of Weight-Average Molecular Weight)

A molecular weight (weight-average molecular weight, Mw) of the polymer of the present invention may be measured by Gel Permeation Chromatography (GPC) using tetrahydrofuran (THF) as a column solvent.

Specifically, 1 ml of THF (degassed) is used for 1 mg of the material to be measured, stirring is conducted at room temperature using a magnetic stirrer for sufficient dissolution, filtration is then conducted using a membrane filter having a pore size of 0.45 to 0.50 μm, and the resulting solution is injected into a Gel Permeation Chromatography (GPC) device.

In the measurement, the column is stabilized at 40° C., tetrahydrofuran is flown at a flow rate of 1 ml/min, and 10 μL of the material in a concentration of 1 mg/l m¹ is injected.

The column is preferably a combination of commercially available polystyrene gel columns. Preferably, the column is a combination of columns selected from Shodex GPC KF-801, 802, 803, 804, 805, 806 and 807 manufactured by SHOWA DENKO K.K. or a combination of columns selected from TSK gel G1000H, G2000H, G3000H, G4000H, G5000H, G6000H, G7000H and TSK guard column manufactured by TOSOH CORPORATON, for example.

Preferable detectors are a refractive index (R1) detector and a UV detector. In measuring a molecular weight of the material, a molecular weight distribution of the material is calculated based on a calibration curve obtained using a monodisperse polystyrene. Preferably, 10 or more points of the polystyrene are used for drawing a calibration curve.

(Measurement of Glass Transition Temperature)

The above-described glass transition temperatures may be measured using a differential scanning calorimeter DSC-7 (manufactured by PerkinElmer Co., Ltd.) or a thermal analysis controller TAC7/DX (manufactured by PerkinElmer Co., Ltd.).

When the differential scanning calorimeter DSC-7 (manufactured by PerkinElmer Co., Ltd.) is used, 4.5 to 5.0 mg of the material is weighed precisely to two decimal places, and the material is encapsulated in an aluminum pan, and then the pan is set in a sample holder of DSC-7.

An empty aluminum pan is used as a reference. The measurement is conducted at a temperature ranging from 0 to 200° C., at a rate of temperature increase of 10° C./min and a rate of temperature decrease of 10° C./min under the temperature control of Heat-Cool-Heat. Data obtained in the second Heat is used for analysis.

After plotting the points according to the temperature indicated in the horizontal axis and an absorption level of heat indicated in the vertical axis, a glass transition temperature is obtained as an intersection point of the extended line of the baseline before a rise of a first heat absorption peak and a tangential line representing the maximum gradient between the rising point of the first peak and the top of the peak.

Specific examples of the conventionally known host compound include the compounds described below and the compounds described in the following documents, for example.

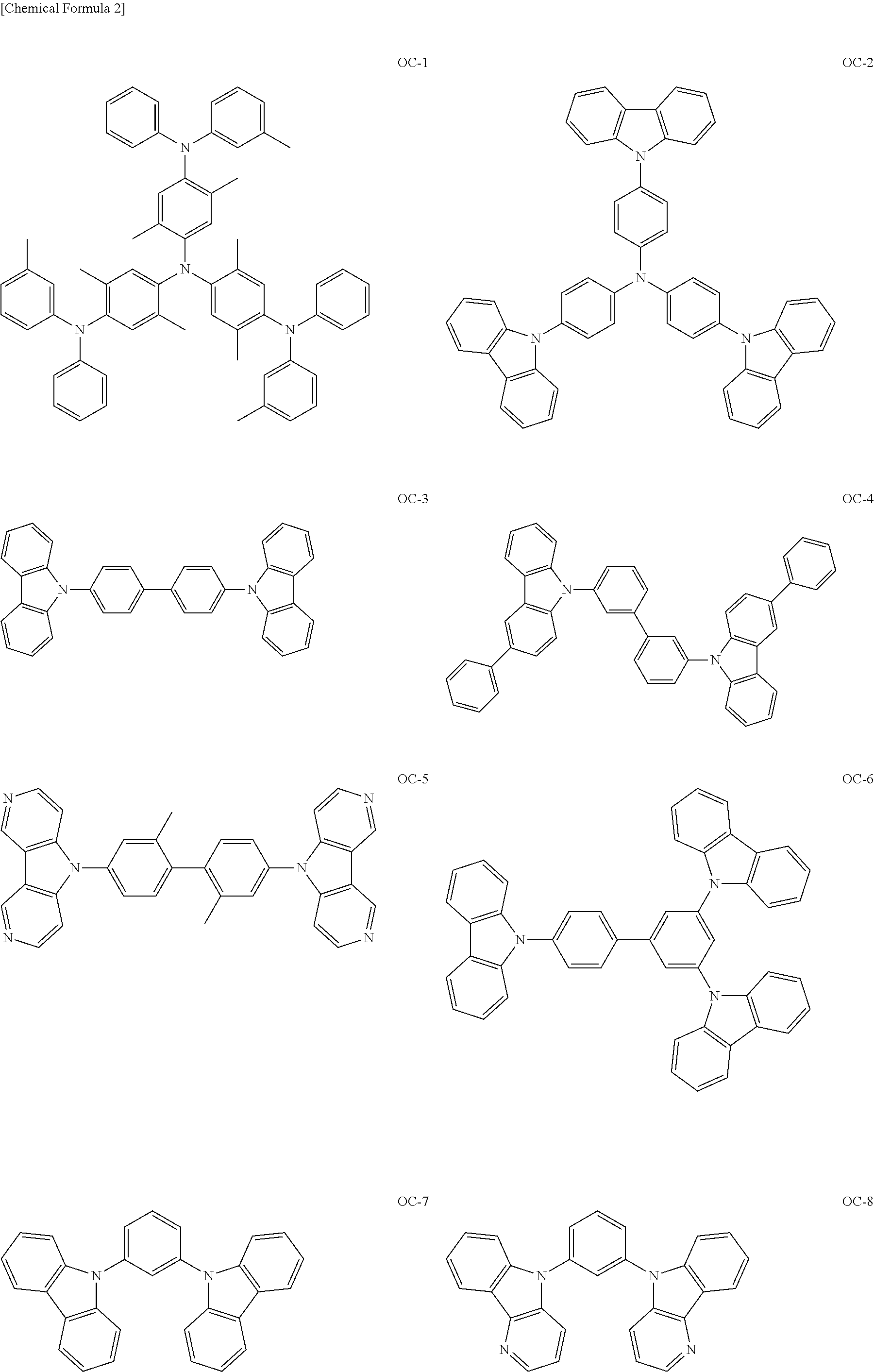

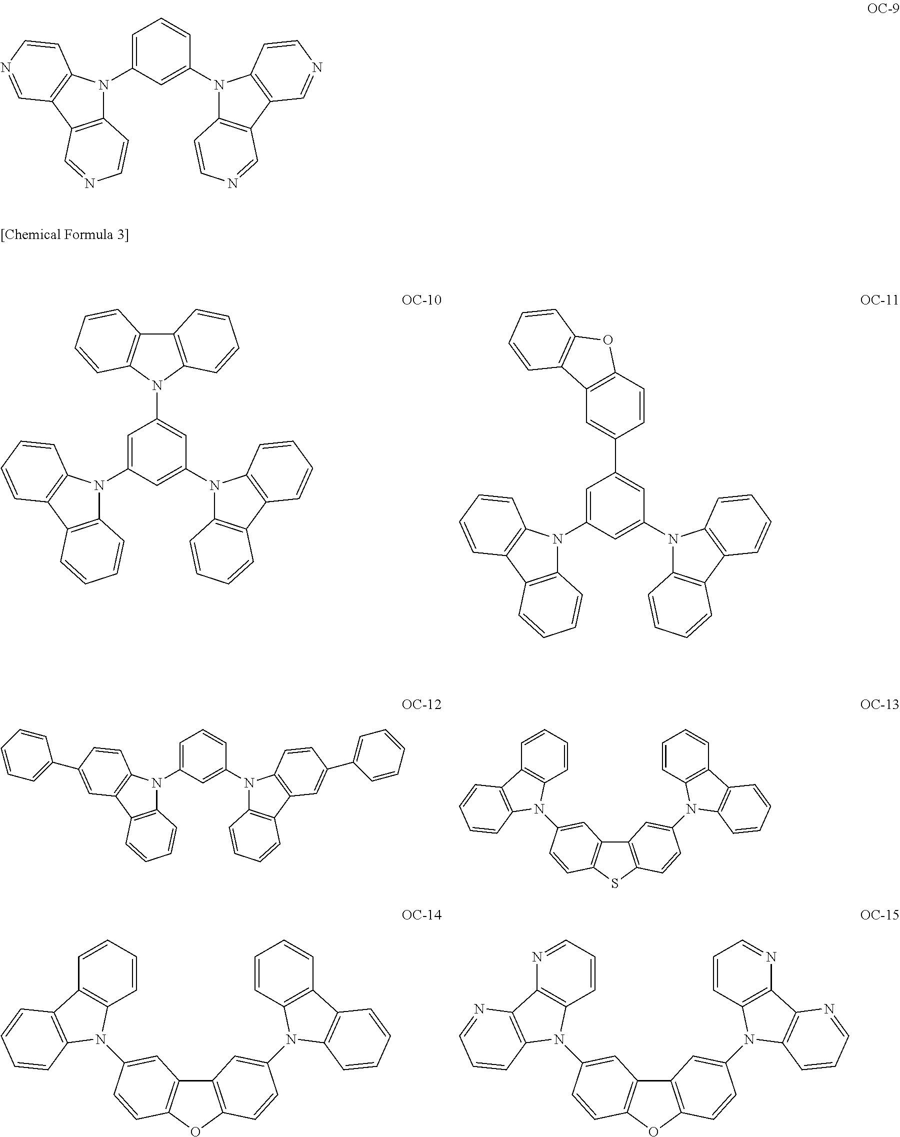

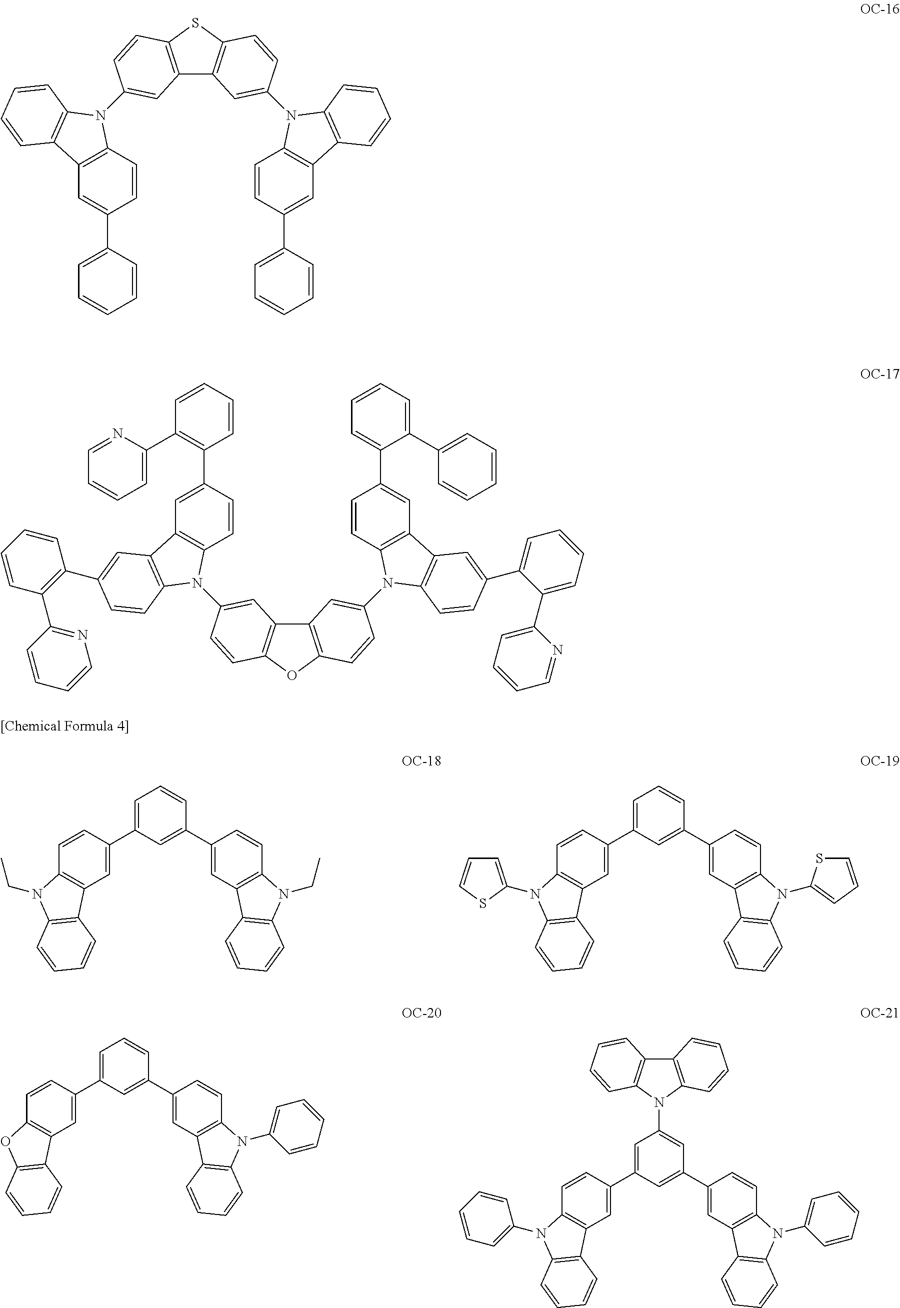

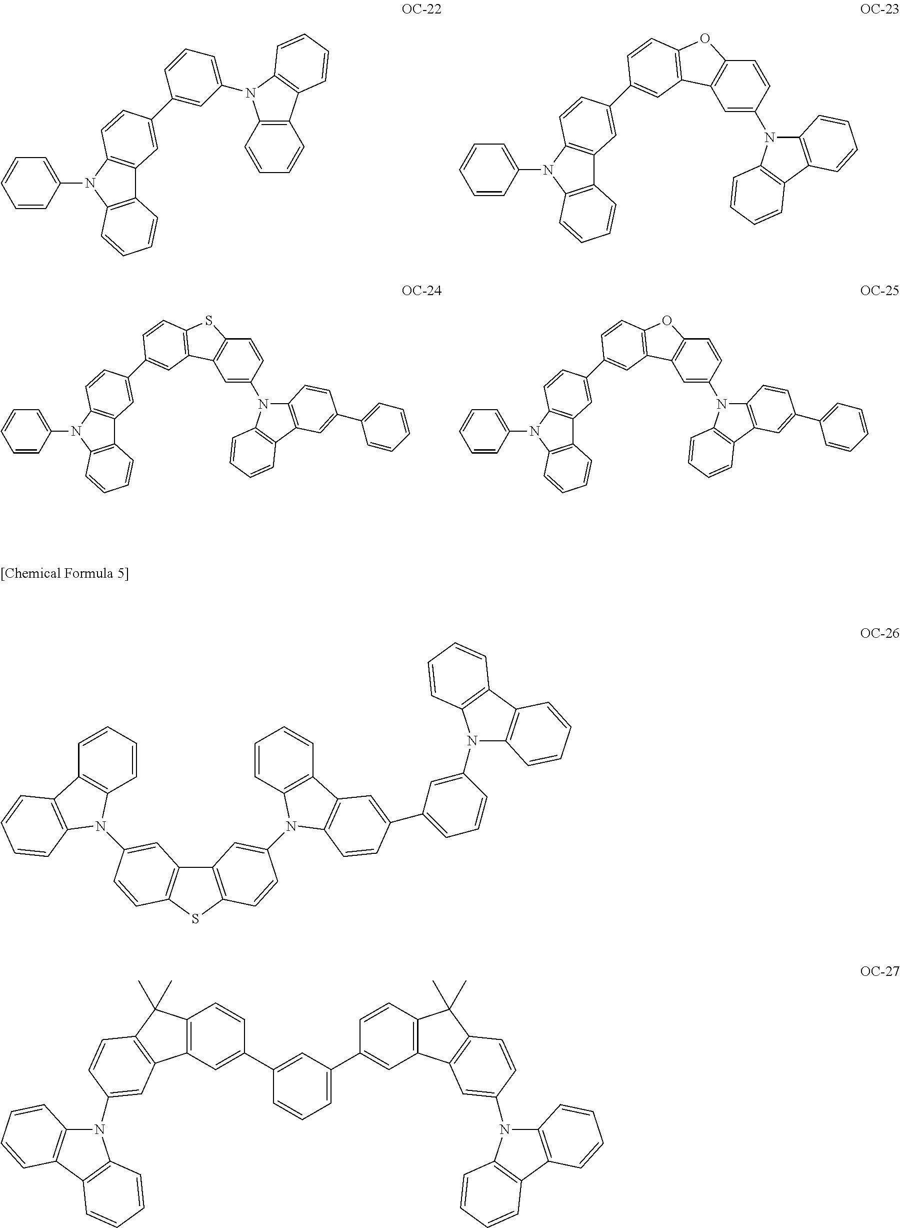

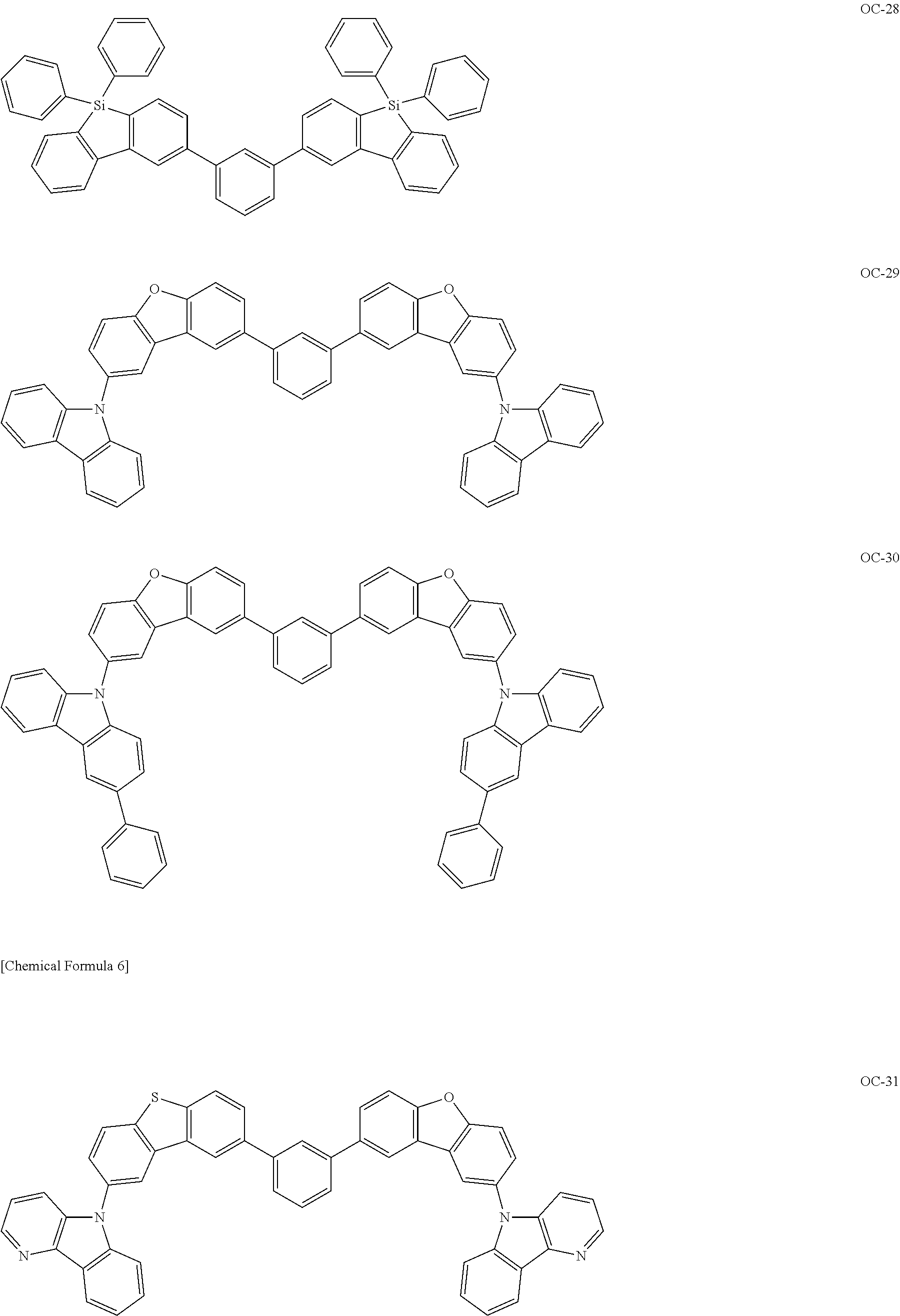 [SMILES: c1ccc([Si]2(c3ccccc3)c3ccccc3-c3cc(-c4cccc(-c5ccc6c(c5)-c5ccccc5[Si]6(c5ccccc5)c5ccccc5)c4)ccc32)cc1 ; c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1 ; c1ccc(-c2ccc3c(c2)c2ccccc2n3-c2ccc3oc4ccc(-c5cccc(-c6ccc7oc8ccc(-n9c%10ccccc%10c%10cc(-c%11ccccc%11)ccc%109)cc8c7c6)c5)cc4c3c2)cc1 ; c1cc(-c2ccc3oc4ccc(-n5c6ccccc6c6ncccc65)cc4c3c2)cc(-c2ccc3sc4ccc(-n5c6ccccc6c6ncccc65)cc4c3c2)c1]

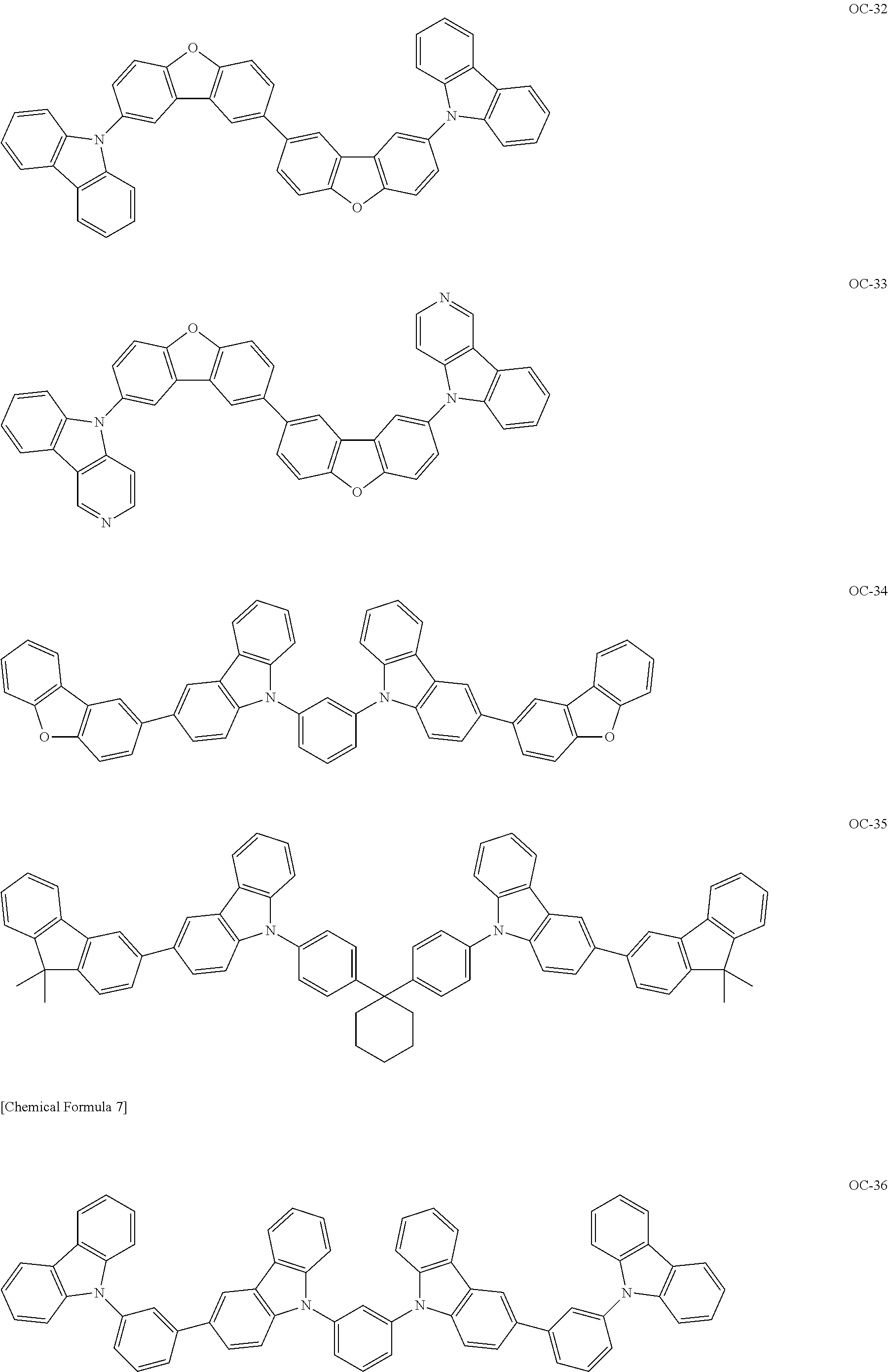

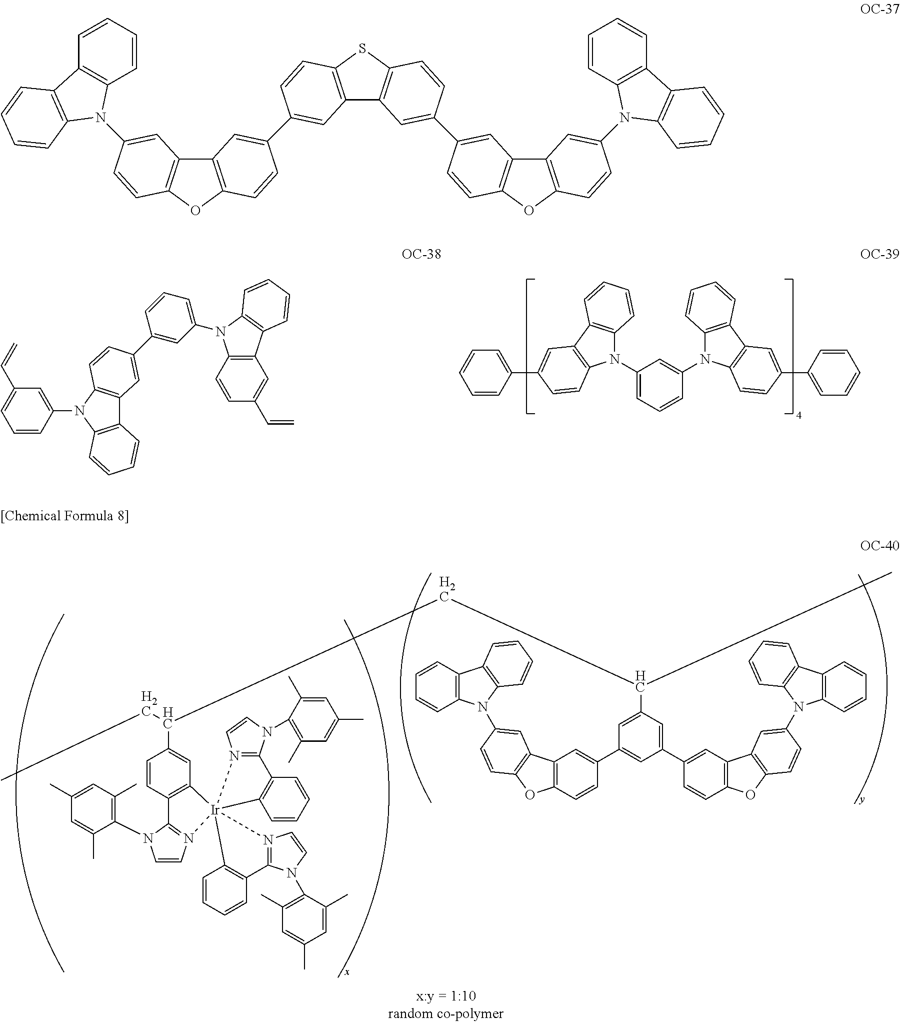

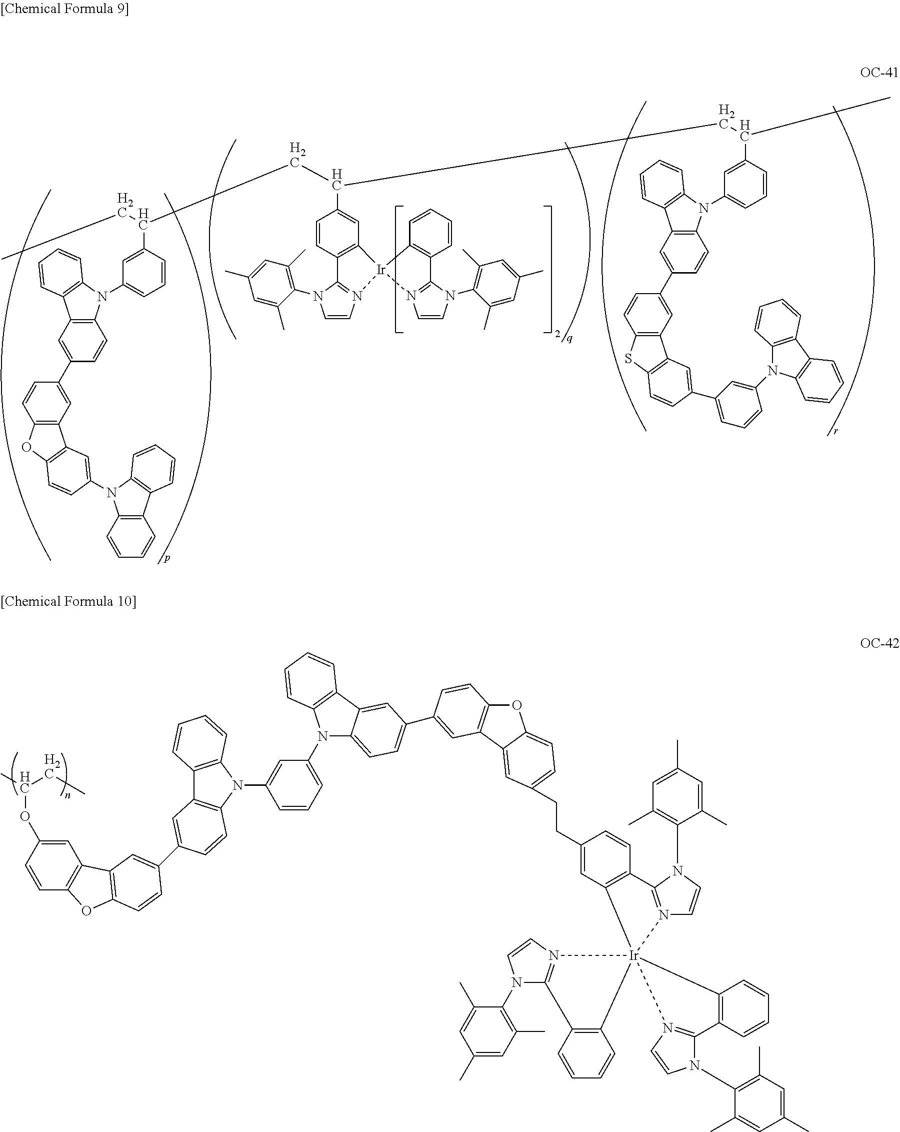

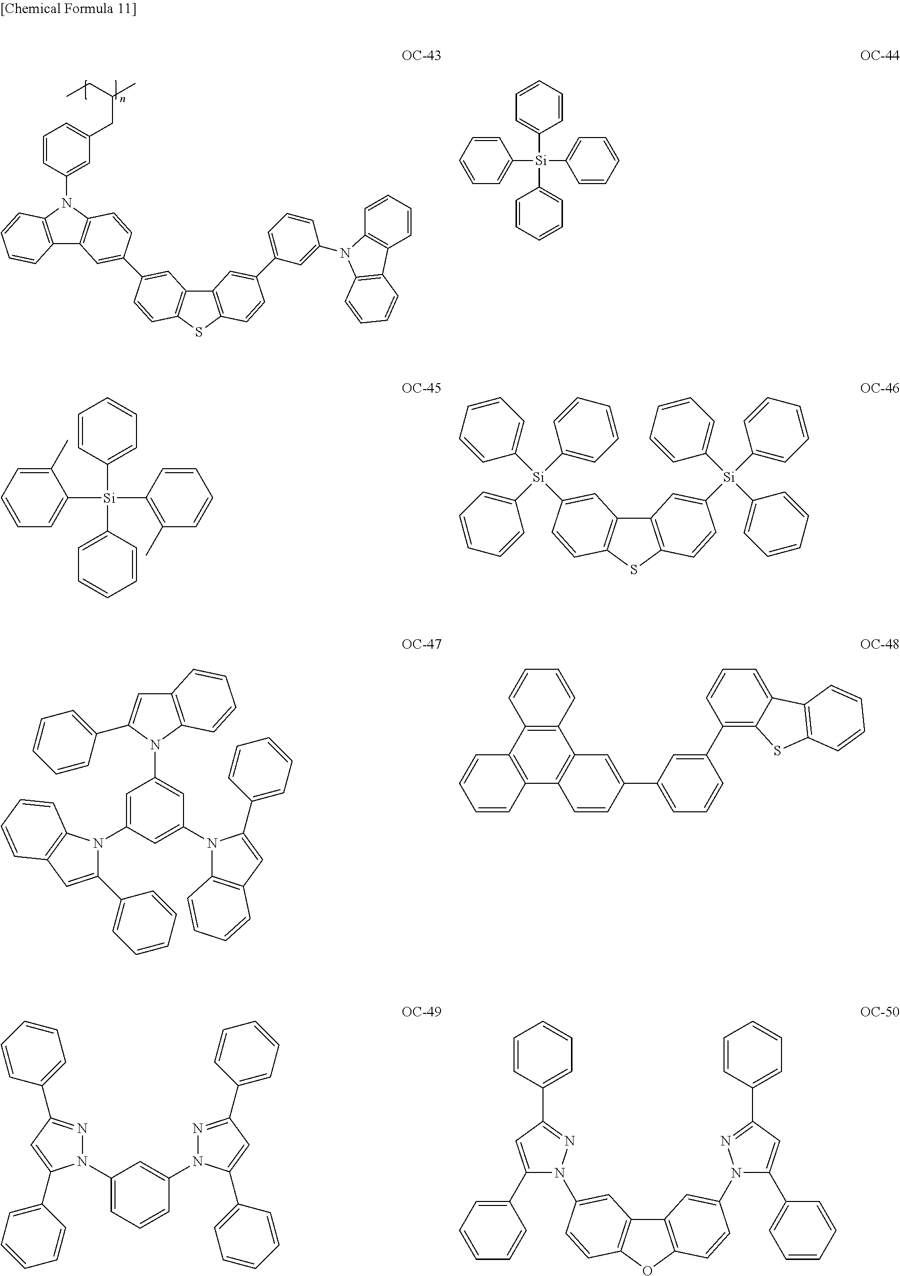

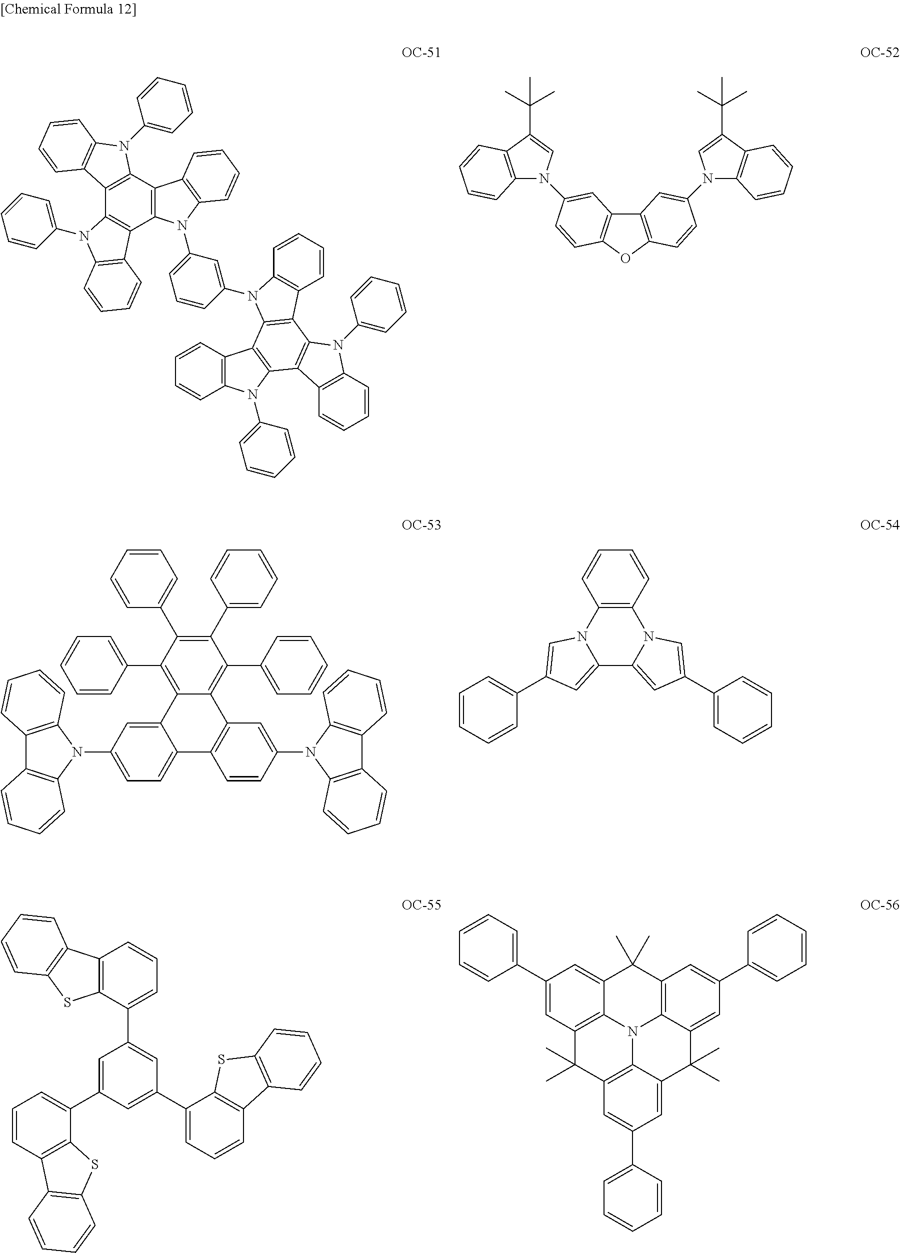

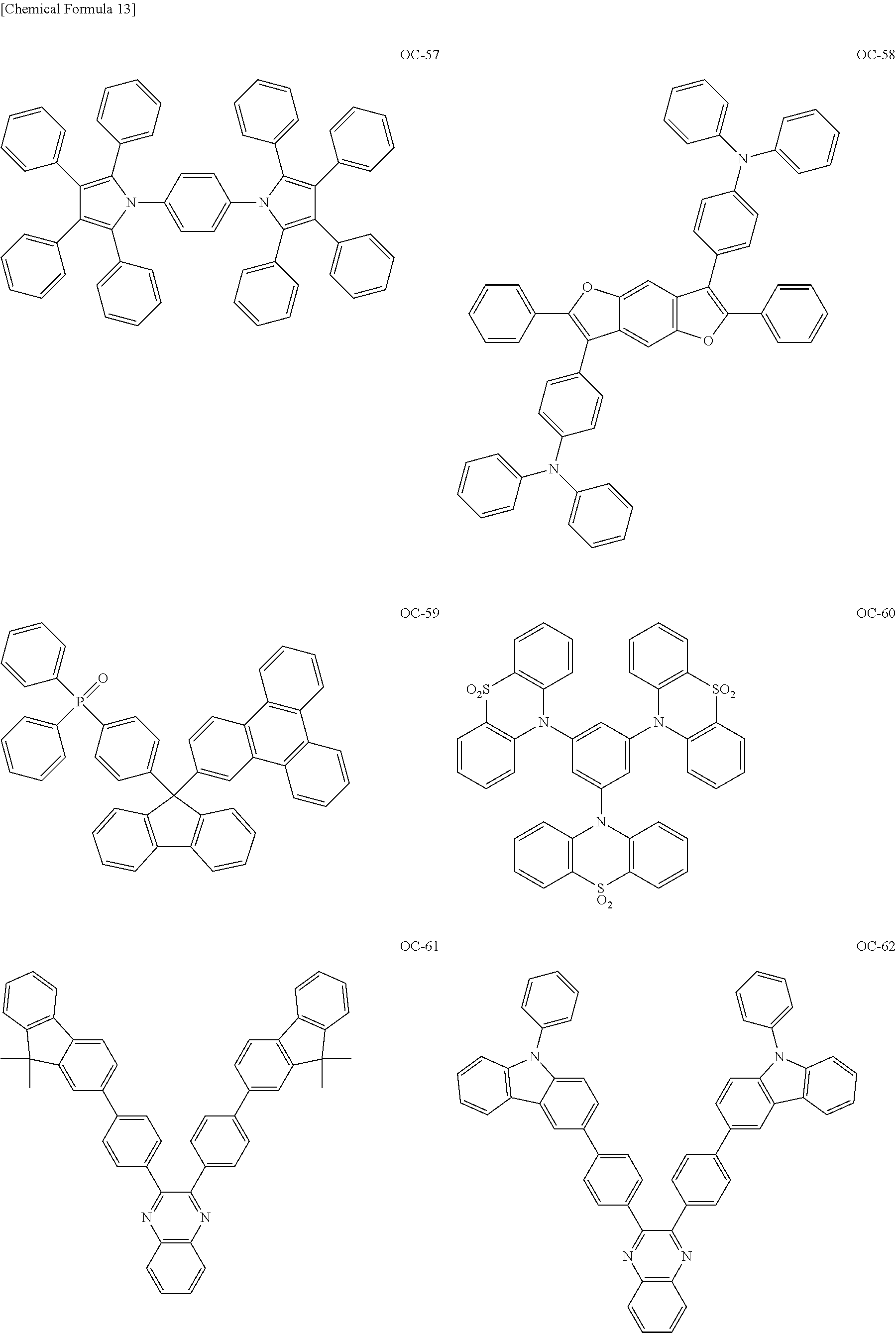

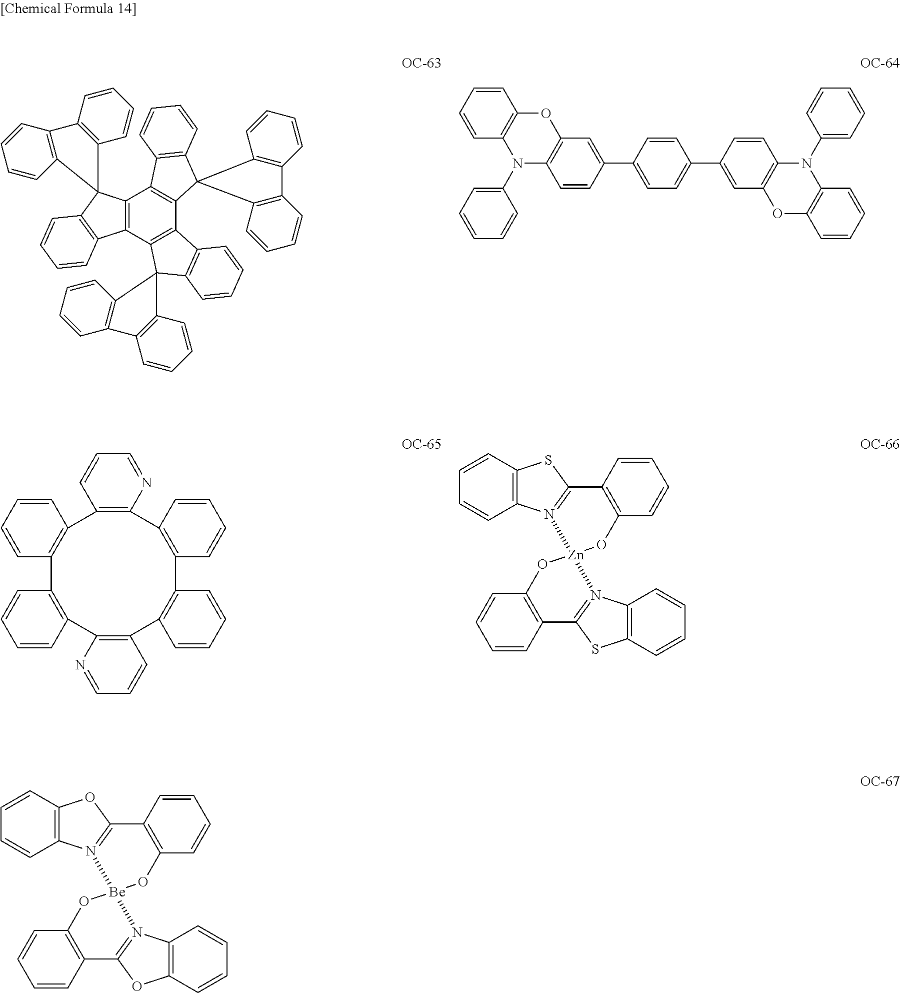

The documents are, for example, Japanese Patent Application Laid-Open Publications Nos. 2001-257076, 2002-308855, 2001-313179, 2002-319491, 2001-357977, 2002-334786, 2002-8860, 2002-334787, 2002-15871, 2002-334788, 2002-43056, 2002-334789, 2002-75645, 2002-338579, 2002-105445, 2002-343568, 2002-141173, 2002-352957, 2002-203683, 2002-363227, 2002-231453, 2003-3165, 2002-234888, 2003-27048, 2002-255934, 2002-260861, 2002-280183, 2002-299060, 2002-302516, 2002-305083, 2002-305084 and 2002-308837.

(Light-Emitting Dopant)

The light-emitting dopant used in the light-emitting layer together with the host material(s) will now be described.

To provide an organic EL element with a higher efficiency, a phosphorescent dopant (s) (also referred to as a phosphorescent body, phosphorescent compound or phosphorescence-emitting compound) are used. A phosphorescent organic metal complex compound is used as the phosphorescent dopant. In the light-emitting layer or light-emitting unit of the organic EL element of the present invention, the phosphorescent organic metal complex compound(s) are included as the light-emitting dopant(s) (or referred to as a light-emitting material) as well as the host compound(s).

The phosphorescent dopant will now be described.

The phosphorescent compound of the present invention is a compound that emits light from the excited triplet. Specifically, the phosphorescent compound is a compound that emits phosphorescence at room temperature (25° C.) and is defined as a compound having a phosphorescence quantum yield of 0.01 or more at 25° C. The phosphorescence quantum yield is preferably 0.1 or more.

The phosphorescence quantum yield can be measured by a method described in page 398 of Spectroscopy II of The 4th Series of Experimental Chemistry 7 (1992, published by Maruzen Co., Ltd.). The phosphorescence quantum yield in a solution can be measured using various solvents. The phosphorescent compound of the present invention may be any compound having the above-mentioned phosphorescence quantum yield (0.01 or more) in a solvent.

There are two principles of light emission by a phosphorescent compound. One is an energy transfer-type, wherein the recombination of carriers occurs on a host compound onto which the carriers are transferred to produce an excited state of the host compound, and then via transfer of this energy to a phosphorescent compound, light emission from the phosphorescent compound occurs. The other is a carrier trap-type, wherein a phosphorescent compound serves as a carrier trap to cause recombination of carriers on the phosphorescent compound, and thereby light emission from the phosphorescent compound occurs.

In each type, the energy in the excited state of the phosphorescent compound is required to be lower than that in the excited state of the host compound.

The phosphorescent compound can be appropriately selected from known compounds that are used in light-emitting layers of organic EL elements.

The phosphorescent compound of the present invention is preferably a complex compound containing a metal of Groups 8 to 10 on the periodic table, more preferably an iridium compound (Ir complex) or a platinum compound (platinum complex type compound), and most preferably an iridium compound (Ir complex).

<<Phosphorescent Organic Metal Complex Compound Represented by Genera Formula (1)>>

A compound represented by the general formula (1) is preferably used as the phosphorescent organic metal complex compound of the present invention.

In the general formula (1), examples of the aromatic hydrocarbon ring represented by A1 include a benzene ring, biphenyl ring, naphthalene ring, azulene ring, anthracene ring, phenanthrene ring, pyrene ring, chrysene ring, naphthacene ring, triphenylene ring, o-terphenyl ring, m-terphenyl ring, p-terphenyl ring, acenaphthene ring, coronene ring, fluorene ring, fluoranthrene ring, naphthacene ring, pentacene ring, perylene ring, pentaphene ring, picene ring, pyrene ring, pyranthrene ring and anthranthrene ring. These rings may also have substituents described later.

In the general formula (1), examples of the aromatic hetero ring represented by A1 include a furan ring, thiophene ring, oxazole ring, pyrrole ring, pyridine ring, pyridazine ring, pyrimidine ring, pyrazine ring, triazine ring, benzimidazole ring, oxadiazole ring, triazole ring, imidazole ring, pyrazole ring, thiazole ring, indole ring, indazole ring, benzoimidazole ring, benzothiazole ring, benzoxazole ring, quinoxaline ring, quinazoline ring, cinnoline ring, quinoline ring, isoquinoline ring, phthalazine ring, naphthyridine ring, carbazole ring, carboline ring and diazacarbazole ring (indicating a carboline ring in which one of carbon atoms constituting the carboline ring is further replaced with a nitrogen atom). These rings may also have substituents described below.

(Substituent)

Examples of the substituent that may be possessed by the aromatic hydrocarbon ring or the aromatic heterocycle formed in A1 include alkyl groups (such as a methyl group, ethyl group, propyl group, isopropyl group, tert-butyl group, pentyl group, hexyl group, octyl group, dodecyl group, tridecyl group, tetradecyl group and pentadecyl group); cycloalkyl groups (such as a cyclopentyl group and cyclohexyl group); alkenyl groups (such as a vinyl group and allyl group); alkynyl groups (such as an ethynyl group and propargyl group); aromatic hydrocarbon groups (also referred to as aromatic hydrocarbon ring groups, aromatic carbon ring groups or aryl groups, such as a phenyl group, p-chlorophenyl group, mesityl group, tolyl group, xylyl group, naphthyl group, anthryl group, azulenyl group, acenaphthenyl group, fluorenyl group, phenanthryl group, indenyl group, pyrenyl group and biphenyryl group); aromatic heterocyclic groups (such as a pyridyl group, pyrimidinyl group, furyl group, pyrrolyl group, imidazolyl group, benzoimidazolyl group, pyrazolyl group, pyrazinyl group, triazolyl group (1,2,4-triazol-1-yl group, 1,2,3-triazol-1-yl group or the like), oxazolyl group, benzoxazolyl group, thiazolyl group, isooxazolyl group, isothiazolyl group, furazanyl group, thienyl group, quinolyl group, benzofuryl group, dibenzofuryl group, benzothienyl group, dibenzothienyl group, indolyl group, carbazolyl group, carbolinyl group, diazacarbazolyl group (a carbolinyl group in which one of the carbon atoms constituting the carboline ring is replaced with a nitrogen atom), quinoxalinyl group, pyridazinyl group, triazinyl group, quinazolinyl group and phthalazinyl group); heterocyclic groups (such as a pyrrolidyl group, imidazolidyl group, morpholyl group and an oxazolidyl group); alkoxy groups (such as a methoxy group, ethoxy group, propyloxy group, pentyloxy group, hexyloxy group, octyloxy group and dodecyloxy group); cycloalkoxy groups (such as a cyclopentyloxy group and cyclohexyloxy group); aryloxy groups (such as a phenoxy group and naphthyloxy group); alkylthio groups (such as a methylthio group, ethylthio group, propylthio group, pentylthio group, hexylthio group, octylthio group and dodecylthio group); cycloalkylthio groups (such as a cyclopentylthio group and cyclohexylthio group); arylthio groups (such as a phenylthio group and naphthylthio group); alkoxycarbonyl groups (such as a methyloxycarbonyl group, ethyloxycarbonyl group, butyloxycarbonyl group, octyloxycarbonyl group and dodecyloxycarbonyl group); aryloxycarbonyl groups (such as a phenyloxycarbonyl group and naphthyloxycarbonyl group); sulfamoyl groups (such as an aminosulfonyl group, methylaminosulfonyl group, dimethylaminosulfonyl group, butylaminosulfonyl group, hexylaminosulfonyl group, cyclohexylaminosulfonyl group, octylaminosulfonyl group, dodecylaminosulfonyl group, phenylaminosulfonyl group, naphthylaminosulfonyl group and 2-pyridylaminosulfonyl group); acyl groups (such as an acetyl group, ethylcarbonyl group, propylcarbonyl group, pentylcarbonyl group, cyclohexylcarbonyl group, octylcarbonyl group, 2-ethylhexylcarbonyl group, dodecylcarbonyl group, phenylcarbonyl group, naphthylcarbonyl group and pyridylcarbonyl group); acyloxy groups (such as an acetyloxy group, ethylcarbonyloxy group, butylcarbonyloxy group, octylcarbonyloxy group, dodecylcarbonyloxy group and phenylcarbonyloxy group); amido groups (such as a methylcarbonylamino group, ethylcarbonylamino group, dimethylcarbonylamino group, propylcarbonylamino group, pentylcarbonylamino group, cyclohexylcarbonylamino group, 2-ethylhexylcarbonylamino group, octylcarbonylamino group, dodecylcarbonylamino group, phenylcarbonylamino group and naphthylcarbonylamino group); carbamoyl groups (such as an aminocarbonyl group, methylaminocarbonyl group, dimethylaminocarbonyl group, propylaminocarbonyl group, pentylaminocarbonyl group, cyclohexylaminocarbonyl group, octylaminocarbonyl group, 2-ethylhexylaminocarbonyl group, dodecylaminocarbonyl group, phenylaminocarbonyl group, naphthylaminocarbonyl group and a 2-pyridylaminocarbonyl group); ureido groups (such as a methylureido group, ethylureido group, pentylureido group, cyclohexylureido group, octylureido group, dodecylureido group, phenylureido group, naphthylureido group and 2-pyridylaminoureido group); sulfinyl groups (such as a methylsulfinyl group, ethylsulfinyl group, butylsulfinyl group, cyclohexylsulfinyl group, 2-ethylhexylsulfinyl group, dodecylsulfinyl group, phenylsulfinyl group, naphthylsulfinyl group and 2-pyridylsulfinyl group); alkylsulfonyl groups (such as a methylsulfonyl group, ethylsulfonyl group, butylsulfonyl group, cyclohexylsulfonyl group, 2-ethylhexylsulfonyl group and dodecyl sulfonyl group); arylsulfonyl and heteroarylsulfonyl groups (such as a phenylsulfonyl group, naphthylsulfonyl group and 2-pyridylsulfonyl group); amino groups (such as an amino group, ethylamino group, dimethylamino group, butylamino group, cyclopentylamino group, 2-ethylhexylamino group, dodecylamino group, anilino group, naphthylamino group and 2-pyridylamino group); halogen atoms (such as a fluorine atom, chlorine atom and bromine atom); fluorinated hydrocarbon groups (such as a fluoromethyl group, trifluoromethyl group, pentafluoroethyl group and pentafluorophenyl group); a cyano group; a nitro group; a hydroxy group; a mercapto group; silyl groups (such as a trimethylsilyl group, triisopropylsilyl group, triphenylsilyl group and phenyldiethylsilyl group); and a phosphono group.

These substituents may be further substituted with the substituent(s) mentioned above. These substituents may combine with each other to form a ring.

In the general formula (1), the aromatic hetero ring represented by A2 corresponds to the aromatic hydrocarbon ring represented by A1 in the general formula (1).

In the general formula (1), examples of the bidentate ligand represented by P1-L1-P2 include substituted or unsubstituted phenylpyridine, phenylpyrazole, phenylimidazole, phenyltriazole, phenyltetrazole, pyrazabole, acetylacetone and picolinic acid.

In the general formula (1), M1 represents a transition metal element (also simply referred to as a transition metal) of Groups 8 to 10 on the periodic table. Preferably, the metal is iridium or platinum, and more preferably iridium.

Specific examples of the compound used as the phosphorescent dopant represented by the general formula (1) are shown below, but the present invention is not limited thereto. These compounds can be synthesized by, for example, the method described in Inorg. Chem., vol. 40, 1704-1711.

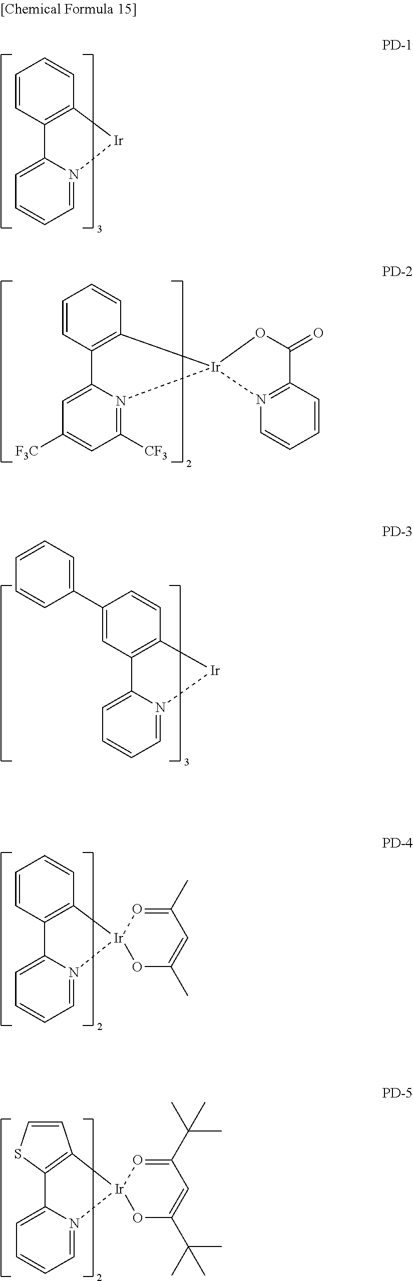

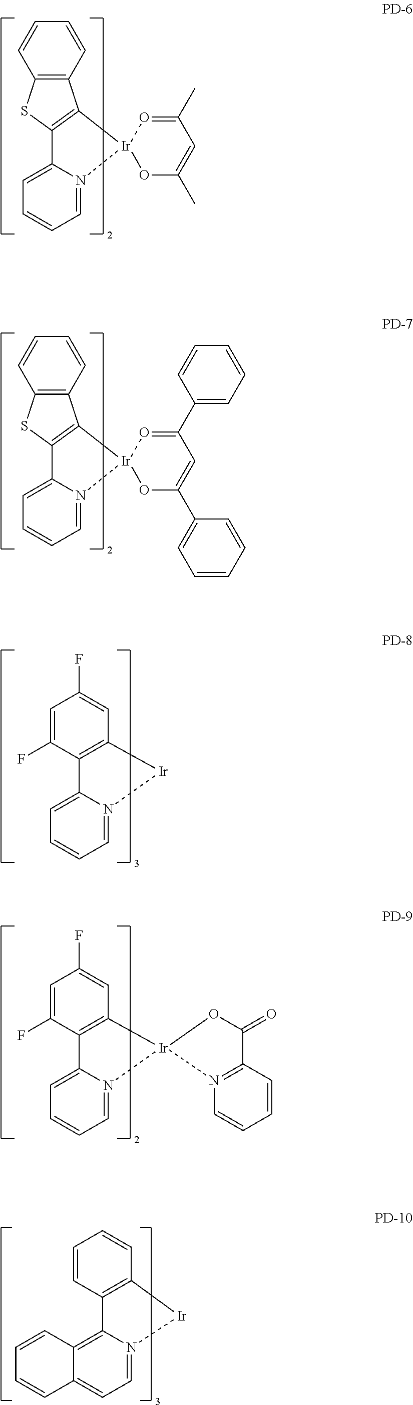

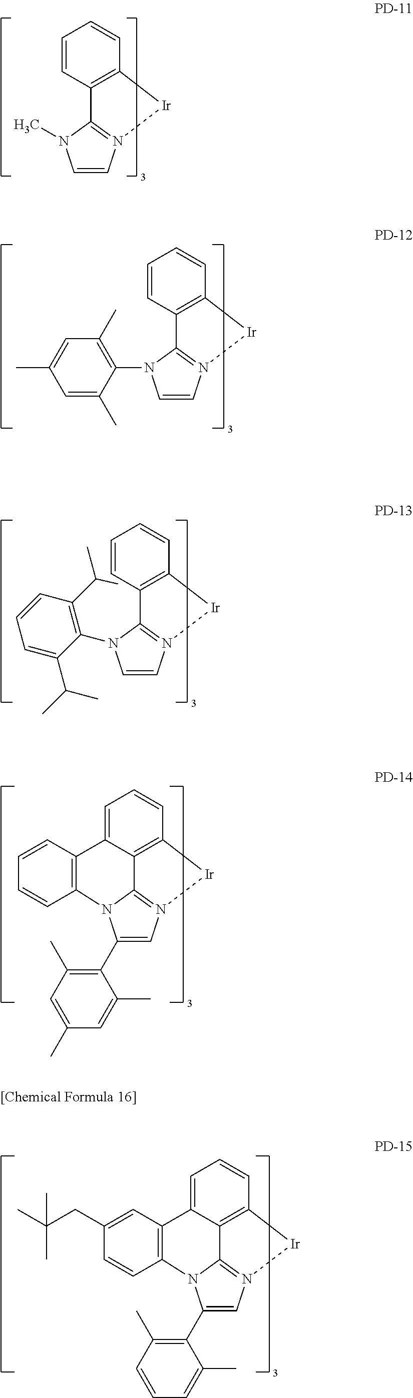

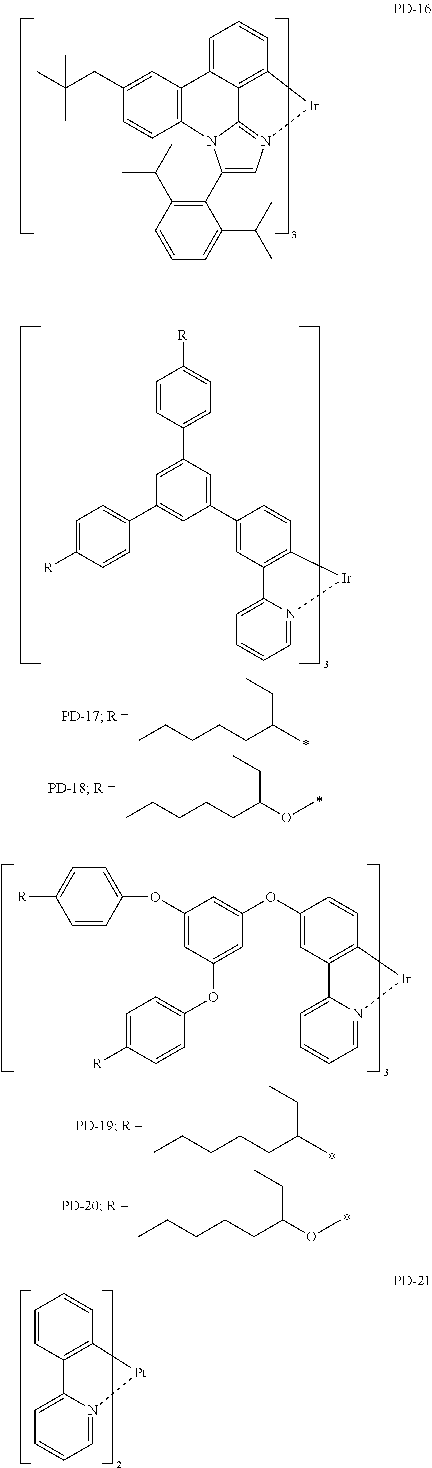

(Fluorescent Dopant (Fluorescent Compound))

The light-emitting layer of the present invention may include a fluorescent dopant(s) in addition to the phosphorescent organic metal complex compound(s).

Examples of the fluorescent dopant (fluorescent compound) include coumarin dyes, pyran dyes, cyanine dyes, chloconium dyes, squarylium dyes, oxobenzanthracene dyes, fluorescein dyes, rhodamine dyes, pyrylium dyes, perylene dyes, stilbene dyes, polythiophene dyes and rare earth fluorescent complexes.

The hole-transporting layer and the electron-transporting layer used as a constituent layers of the organic EL element of the present invention will now be described. In addition, an injecting layer and a blocking layer are also described.

<<Injecting Layer: Electron-Injecting Layer and Hole-Injecting Layer>>

The injecting layers, i.e., an electron-injecting layer and a hole-injecting layer, may be disposed between the anode and the light-emitting layer or the electron hole-transporting layer and between the cathode and the light-emitting layer or the electron-transporting layer.

The injecting layer is provided between the electrode and the organic layer in order to reduce the driving voltage and to improve the luminance. Such an injecting layer is described in detail in “Electrode material”, Div. 2 Chapter 2 (pp. 123-166) of “Organic EL element and its frontier of industrialization” (published by NTS Corporation, Nov. 30, 1998). The injecting layers are classified into a hole-injecting layer (anode buffer layer) and an electron-injecting layer (cathode buffer layer).

The anode buffer layer (electron hole-injecting layer) is also described in detail in Japanese Patent Laid-Open Application Publications Nos. Hei9-45479, Hei9-260062 and Hei8-288069, for example, and specific examples thereof include phthalocyanine buffer layers as typified by a copper phthalocyanine layer, oxide buffer layers as typified by a vanadium oxide layer, amorphous carbon buffer layers, and polymer buffer layers employing electroconductive polymers such as polyaniline (emeraldine) or polythiophene. The cathode buffer layer (electron-injecting layer) is also described in detail in Japanese Patent Laid-Open Application Publications Nos. Hei6-325871, Hei9-17574 and Hei10-74586, for example, and specific examples thereof include metal buffer layers as typified by a strontium or aluminum layer, alkali metal compound buffer layers as typified by a lithium fluoride layer, alkali earth metal compound buffer layers as typified by a magnesium fluoride layer and oxide buffer layers as typified by an aluminum oxide. The buffer layer (injecting layer) is preferably very thin and has a thickness in a range of 0.1 to 10 nm, while a preferable thickness depends on the material.

<<Blocking Layer: Hole-Blocking Layer and Electron-Blocking Layer>>

The blocking layer is provided in addition to fundamental constituent layers of the organic compound thin film as described above as needed. Examples of the blocking layer include hole-blocking layers described in Japanese Patent Laid-Open Application Publications Nos. Hei11-204258 and Hei11-204359 and on page 237 of “Organic EL element and its frontier of industrialization” (published by NTS Corporation, Nov. 30, 1998), for example.

The hole-blocking layer functions as an electron-transporting layer in a broad sense and is composed of a material having electron-transporting properties but extremely poor hole-transporting properties. The hole-blocking layer can increase the probability of recombination of electrons and holes by transporting electrons and blocking holes.

The configuration of an electron-transporting layer described below can be applied to the hole-blocking layer according to the present invention as needed.

In the present invention, when a plurality of light-emitting layers that emit lights of different colors are provided, a light-emitting layer emitting light whose maximum emission wavelength is the shortest in all of the light-emitting layers is preferably disposed so as to be the closest to the anode. In such a case, an additional hole-blocking layer is preferably disposed between the light-emitting layer emitting light whose maximum emission wavelength is the shortest and a light-emitting layer that is the next closest to the anode.

Furthermore, at least 50% by mass of the compounds contained in the hole-blocking layer disposed at the position described above preferably has an ionization potential of 0.3 eV or more higher than that of the host compound contained in the light-emitting layer emitting light whose maximum emission wavelength is the shortest.

The ionization potential is defined as energy necessary for releasing an electron in the highest occupied molecular orbital (HOMO) level of a compound to the vacuum level and can be determined by the following way, for example.

(1) Molecular orbital calculation software, Gaussian 98 (Gaussian 98, Revision A.11.4, M. J. Frisch, et al., Gaussian, Inc., Pittsburgh Pa., 2002) manufactured by Gaussian, Inc. in U.S.A. is used. The ionization potential is obtained by rounding off the value (eV unit conversion value) to the second decimal place, the value being calculated by structural optimization using B3LYP/6-31G* as a keyword. This calculated value is valid because of a high correlation between the calculated values determined by such a method and experimental values.

(2) The ionization potential can also be obtained by direct photoelectron spectroscopic measurement. For example, a low-energy electron spectrometer “Model AC-1”, manufactured by Riken Keiki Co., Ltd. or a method known as ultraviolet photoelectron spectroscopy can be suitably employed.

On the other hand, the electron-blocking layer functions as a hole-transporting layer in a broad sense and is composed of a material having hole-transporting properties but extremely poor electron-transporting properties. The electron-blocking layer can increase the probability of recombination of electrons and holes by transporting holes and blocking electrons.

The configuration of a hole-transporting layer described below can be applied to the electron-blocking layer as needed. The hole-blocking layer and the electron-transporting layer of the present invention each preferably has a thickness of 3 to 100 nm, and more preferably to 30 nm.

<<Hole-Transporting Layer>>

The hole-transporting layer is composed of a hole-transporting material(s) having hole-transporting properties. One or more hole-transporting layers may be provided.

The hole-transporting material has hole-injecting or transporting properties or electron-blocking properties, and may be either an organic material or inorganic material. Examples of the electron hole-transporting material include triazole derivatives, oxadiazole derivatives, imidazole derivatives, polyarylalkane derivatives, pyrazoline derivatives, pyrazolone derivatives, phenylenediamine derivatives, arylamine derivatives, amino substituted chalcone derivatives, oxazole derivatives, styryl anthracene derivatives, fluorenone derivatives, hydrazone derivatives, stilbene derivatives, silazane derivatives, aniline copolymers and electroconductive polymer oligomers, and particularly thiophene oligomers and the like.

As the hole-transporting material, those described above can be used, but preferred are porphyrin compounds, aromatic tertiary amine compounds, and styrylamine compounds. In particular, aromatic tertiary amine compounds are preferably used.

Typical examples of the aromatic tertiary amine compound and the styrylamine compound include N,N,N′,N′-tetraphenyl-4,4′-diaminophenyl; N,N′-diphenyl-N,N′-bis(3-methylphenyl)-4,4′-diamine (TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-methylphenyl)phenylmethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminodiphenyl ether; 4,4′-bis(diphenylamino)quaterphenyl; N,N,N-tri(p-tolyl)amine, 4-(di-p-tolylamino)-4′-[4-(di-p-tolylamino)styryl]stilbene; 4-N,N-diphenylamino-(2-diphenylvinyl)benzene; 3-methoxy-4′-N,N-diphenylaminostylbenzene;
N-phenylcarbazole; compounds having two condensed aromatic rings in the molecule described in U.S. Pat. No. 5,061,569, such as 4,4′-bis[N-(1-naphthyl)-N-phenylamino]biphenyl (NPD), and a compound described in Japanese Patent Laid-Open No. Hei4-308688, 4,4′,4″-tris[N-(3-methylphenyl)-N-phenylamino]triphenylamine (MTDATA) in which three triphenylamine units are bonded in a starburst form.

Polymer materials including the above-mentioned compounds introduced into their polymer chains and polymer materials including the above-mentioned compounds as their main chains are preferably used.

So-called p-type hole-transporting materials as described in Japanese Patent Laid-Open Application Publication No. Hei11-251067 and in J. Huang, et al., (Applied Physics Letters, 80 (2002), p. 139) can also be used.

The hole-transporting layer can be obtained by forming a thin layer using the above hole-transporting material(s) by a known method such as vacuum deposition, spin coating, casting, printing including ink jetting or LB method. In the present invention, the hole-transporting layer is preferably formed by application (wet process). The thickness of the hole-transporting layer may have any value and is usually about 5 nm to 5 μm, and preferably 5 to 200 nm. The hole-transporting layer may have a monolayer structure composed of one or more of the materials mentioned above.

A hole-transporting layer having high p-type properties doped with impurity(ies) can also be used. Examples thereof include those described in, for example, Japanese Patent Laid-Open Application Publications Nos. Hei4-297076, 2000-196140 and 2001-102175, and J. Appl. Phys., 95, 5773 (2004).

In the present invention, the use of such hole-transporting layer having high p-type properties is preferable for providing an element with lower power consumption.

For the hole-transporting layer, an acceptor material(s) are preferably used. Examples of the acceptor materials include n-type semiconductor materials. Examples of the n-type semiconductor materials include inorganic materials such as AU, Pt, W, Ir, POCl₃, AsF₆, Cl, Br, I, vanadium oxide (V₂O₅), molybdenum oxide (MoO₂), and compounds containing a cyano group(s) and fluorine atom(s) such as 7,7,8,8-tetracyanoquinodimethane (TCNQ) and tetrafluorotetracyanoquinodimethane (F4-TCNQ). Examples further include polymer compounds containing tris(4-bromophenyl) aminium hexachloro antimonite (TBPAH), fullerene, octa azaporphyrin, perfluoro compounds of p-type semiconductors (such as perfluoro pentacene and perfluoro phthalocyanine), or an aromatic carboxylic acid anhydride(s) or their imides such as naphthalene tetracarboxylic anhydride, naphthalene tetracarboxylic diimide, perylene tetracarboxylic anhydride and perylene tetracarboxylic diimide as the polymers' backbones.

Among them, polymer compounds containing fullerene are preferable. Examples of the fullerene-containing polymer compounds include polymer compounds containing fullerene C60, fullerene C70, fullerene C76, fullerene C78, fullerene C84, fullerene C240, fullerene C540, mixed fullerene, fullerene nanotube, multi-layered nanotube, mono-layered nanotube or nanohorn (cone-shaped). Among the fullerene-containing polymer compounds, polymer compounds containing fullerene C60 (or their derivatives) are preferable.

Fullerene-containing polymers are categorized into polymers where fullerenes are branched from the polymers' main chains and polymers where fullerenes are incorporated into the polymers' main chains. Polymers where fullerenes are incorporated into the polymers' main chains are preferable.

In the present invention, the hole-transporting material included in the hole-transporting layer is selected from the materials having Tgs higher than Tg of the host compound(s) of the light-emitting layer or Tg of the light-emitting layer. The hole-transporting layer composed of a polymer(s) is preferable to have a Tg higher than that of the light-emitting layer.

Preferably, the electron-transporting material described later is also a polymer. Preferably, both of the hole-transporting material(s) and the electron-transporting material(s) are polymers.

Examples of the hole-transporting materials preferably used in the present invention will now be shown, but the present invention is not limited thereto.

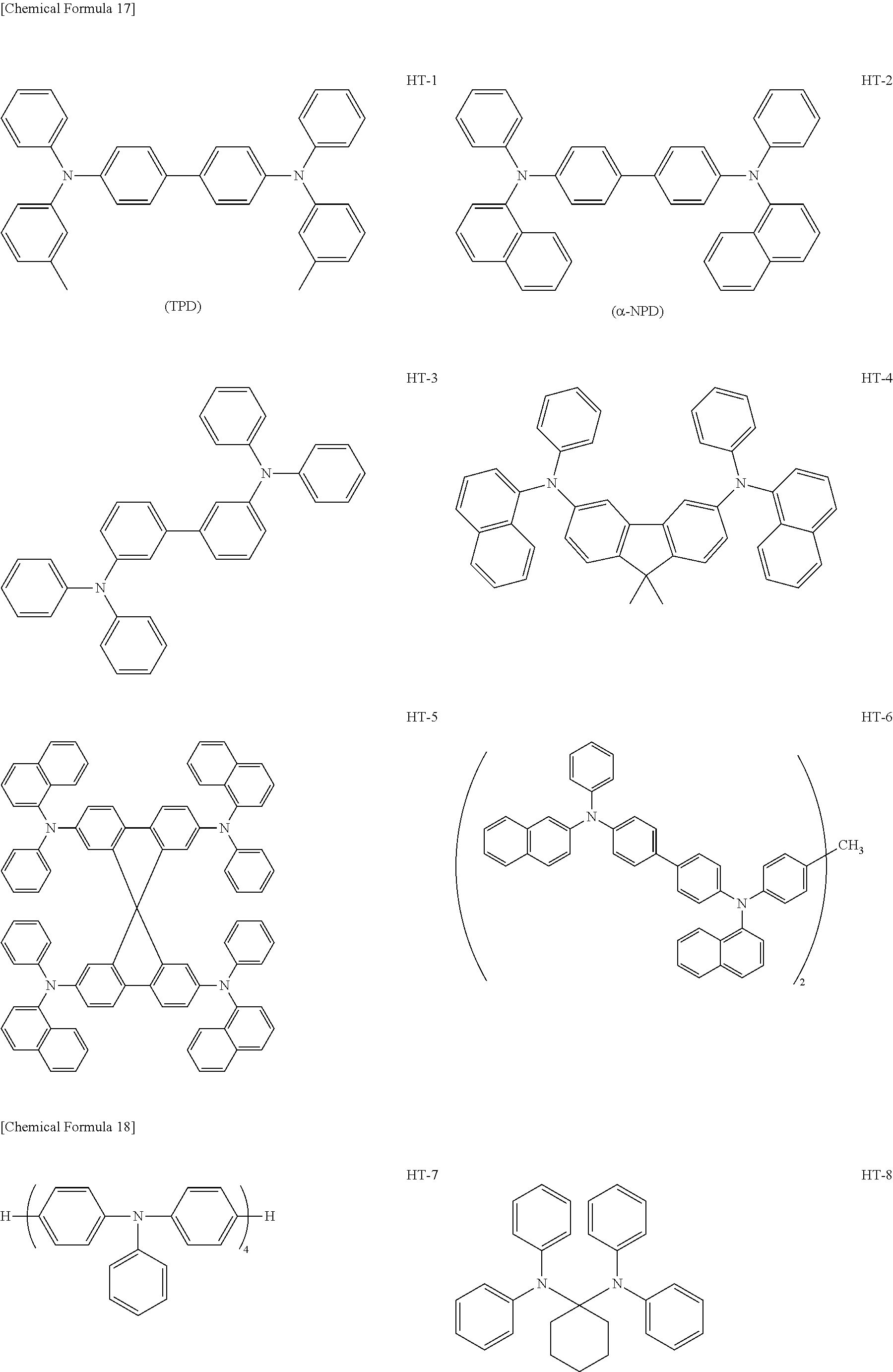

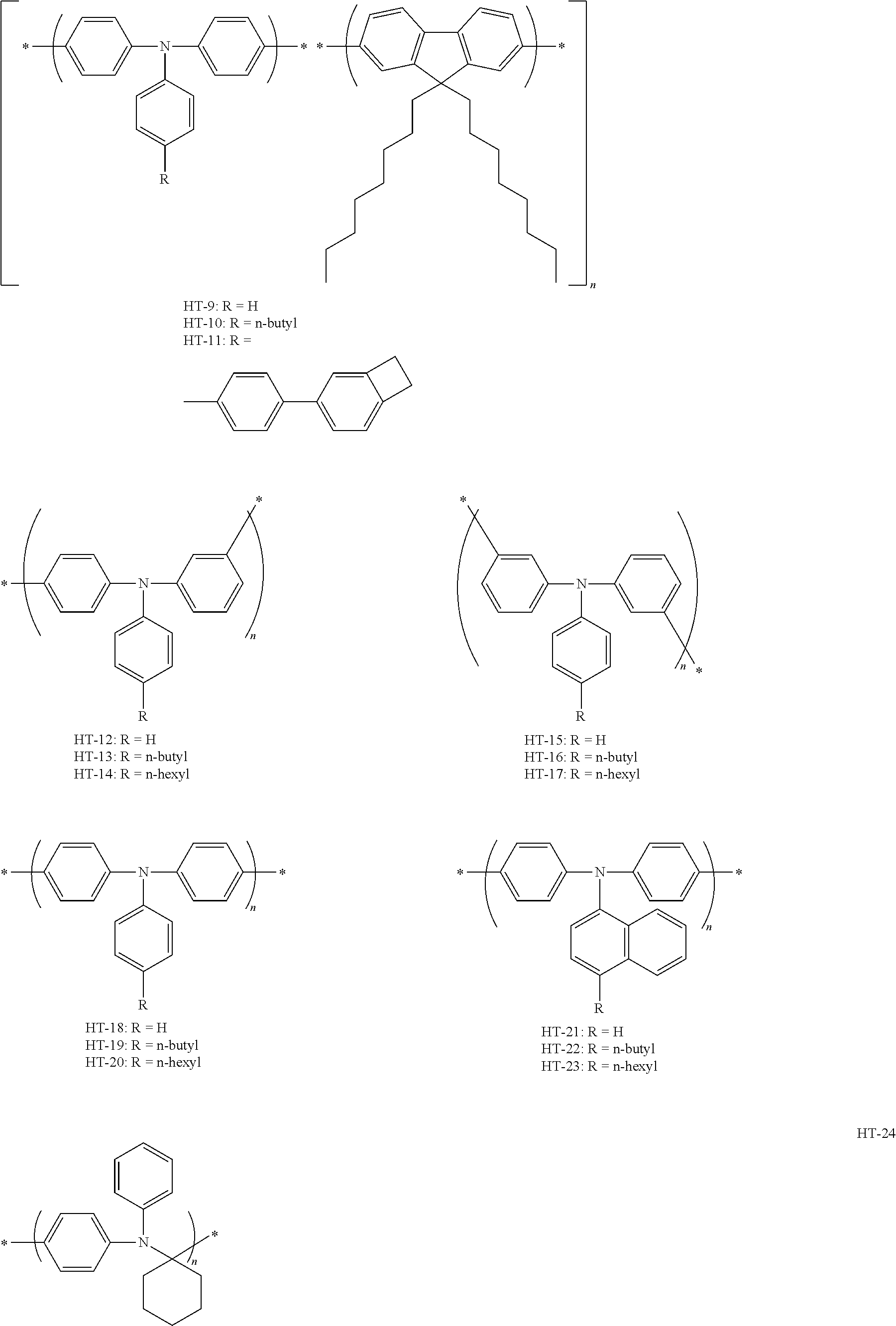

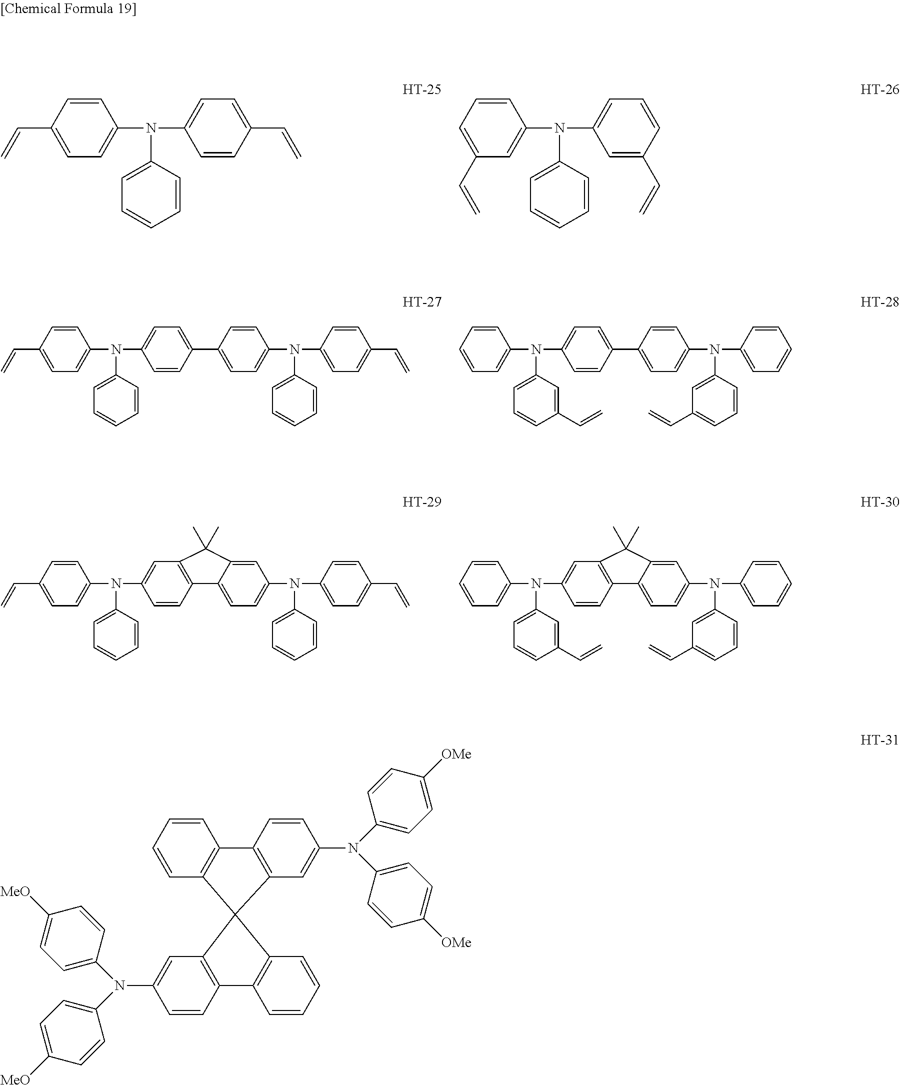

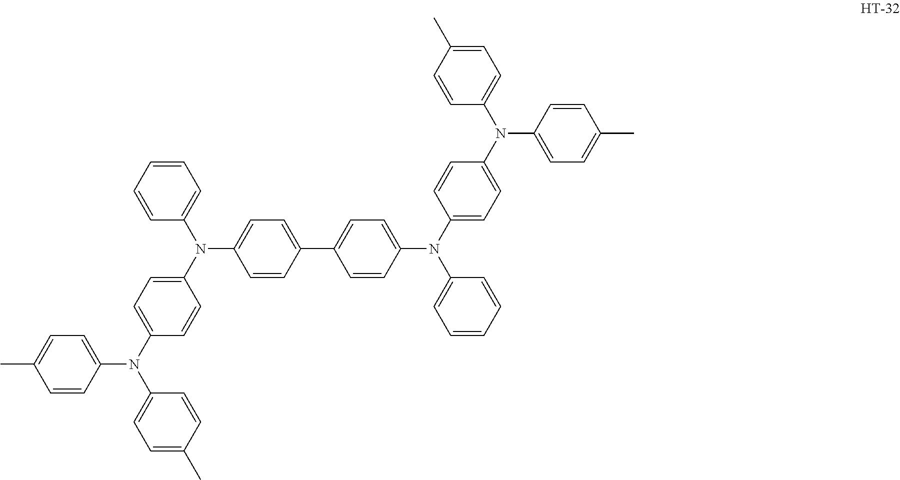

<<Electron-Transporting Layer>>

The electron-transporting layer is composed of a material having an electron-transporting function, and the electron-injecting layer and the hole-blocking layer are included in the electron-transporting layer in a broad sense. One or more electron-transporting layers may be provided.

Conventionally, an electron-transporting material (also used as a hole-blocking material), the electron-transporting material being included in the electron-transporting layer when one electron-transporting layer is provided or included in the electron-transporting layer adjacent to the light-emitting layer on the cathode side when multiple electron-transporting layers are provided, may be any material having a function for transporting electrons injected from a cathode to the light-emitting layer and may be appropriately selected from known compounds.

Examples of the electron-transporting material include nitro-substituted fluorene derivatives, diphenylquinone derivatives, thiopyran dioxide derivatives, carbodiimides, fluolenylidenemethane derivatives, anthraquinodimethane and anthrone derivatives, and oxadiazole derivatives.

Thiadiazole derivatives in which oxygen atoms of the oxadiazole rings of the oxadiazole derivatives mentioned above are replaced with sulfur atoms and quinoxaline derivatives having quinoxaline rings known as electron-extracting groups may also be used as the electron-transporting materials. Polymer materials including these compounds introduced into their polymer chains or polymer materials including the compounds as their main chains may also be used.

Examples of the electron-transporting material include metal complexes of 8-quinolinol derivatives such as aluminum tris(8-quinolinol) (Alq), aluminum tris(5,7-dichloro-8-quinolinol), aluminum tris(5,7-dibromo-8-quinolinol), aluminum tris(2-methyl-8-quinolinol), aluminum tris(5-methyl-8-quinolinol), and zinc bis(8-quinolinol) (Znq) and metal complexes in which the central metals of the metal complexes mentioned above are replaced with In, Mg, Cu, Ca, Sn, Ga or Pb.

In addition, a metal-free or metal-containing phthalocyanine and its derivative having an end substituted with, for example, an alkyl group or a sulfonic acid group are also preferably used as the electron-transporting materials. The distyrylpyrazine derivatives exemplified as materials for the light-emitting layer can be preferably used as the electron-transporting material. An inorganic semiconductor such as n-type Si and n-type SiC may also be used as the electron-transporting material like the hole-injecting layer or the hole-transporting layer.

The electron-transporting layer may be obtained by forming a thin film with the above-mentioned electron-transporting material(s) by a known method such as vacuum deposition, spin coating, casting, printing including ink jetting or LB method.

The thickness of the electron-transporting layer may have any value without particular limitation and is usually about 5 nm to 5 μm, and preferably 5 to 200 nm. The electron-transporting layer may have a monolayer structure composed of one or more of the materials mentioned above.

An electron-transporting layer having high n-type properties doped with impurity(ies) can be used. Examples thereof include those described in, for example, Japanese Patent Laid-Open Application Publications Nos. Hei-4-297076, Hei10-270172, 2000-196140 and 2001-102175, and J. Appl. Phys., 95, 5773 (2004).

In the present invention, the use of such electron-transporting layer having high n-type properties is preferable for providing an element with lower power consumption.

In the electron-transporting layer, a donor material(s) are preferably included. Examples of the donor materials include alkali metals, alkali earth metals, rare earth elements, inorganic materials such as Al, Ag, Cu and In, organic or inorganic salts of alkali metals, salts of alkali earth metals, arylamines such as aniline, phenylenediamine and N,N′-di(naphthalene-1-yl)-N-N′-diphenyl-benzidine, various condensed polycyclic aromatic compounds and conjugate compounds.

Examples of the condensed polycyclic aromatic compounds include anthracene, tetracene, pentacene, hexacene, heptacene, chrysene, picene, fulminene, pyrene, peropyrene, perylene, terrylene, quaterrylene, coronene, ovalene, circumflex anthracene, bisanthene, zethrene, heptazethrene, pyranthrene, bioranthene, isobioranthene, circobiphenyl, anthradithiophene, their derivatives and their precursors.

Examples of the conjugated compounds include polythiophene, thiophene oligomers, polypyrrole, pyrrole oligomers, polyaniline, polyphenylene, phenylene oligomers, polyphenylenevinylene, phenylenevinylene oligomers, polyethylenevinylene, ethylenevinylene oligomers, polyacetylene, polydiacetylene, tetrathiafulvalene compounds, quinone compounds, cyan compounds such as tetracyanoquinodimethane, fullerene, their derivatives and mixtures of them.

In polythiophene and thiophene oligomers, hexamers of thiophene such as α-sexithiophene; α, ω-dihexyl-α-sexithiophene; α, ω-dihexyl-α-quinquethiophene; α, ω-bis(3-butoxypropyl)-usexithiophene are preferably used.

Examples of the p-type semiconductor polymers include polyacetylene, polyparaphenylene, polypyrrole, polyparaphenylene sulfide, polythiophene, polyphenylenevinylene, polycarbazole, polyisothianaphthene, polyheptadiyne, polyquinoline, polyaniline, substituted-non-substituted alternating thiophene copolymers described in Japanese Patent Application Laid-Open Publication No. 2006-36755, polymers containing a fused thiophene ring(s) described in Japanese Patent Application Laid-Open Publications Nos. 2007-51289 and 2005-76030, J. Amer. Chem. Soc., 2007, p. 4112 and J. Amer. Chem. Soc., 2007, p. 7246, thiophene copolymers described in WO2008/000664, Adv. Mater., 2007, p. 4160, Macromolecules, 2007, Vol. 40, p. 1981, and the like.

In addition, employable compounds further include organic molecule complexes such as porphyrin, phthalocyanine copper, tetrathiafulvalene (TTF)-tetracyanoquinodimethane (TCNQ) complex, bisethylenetetrathiafulvalene (BEDTTTF)-perchloric acid complex, BEDTTTF-iodine complex and TCNQ-iodine complex; fullerenes such as C60, C70, C76, C78 and C84; carbon nanotubes such as SWNT; dyes such as merocyanine dyes and hemicyanine dyes, a conjugation polymers such as polysilane and polygermane; and composites of organic and inorganic materials described in Japanese Patent Application Laid-Open Publication No. 2000-260999, for example.

Among these conjugation materials, it is preferable that at least one of fused polycyclic aromatic compounds such as pentacene, fullerenes, fused ring-tetracarbonic acid diimides, metal phthalocyanines and metal porphyrins is used. Pentacenes are more preferable.

Examples of pentacenes include pentacene derivatives containing substituents described in International Publications Nos. WO03/16599 and WO03/28125, U.S. Pat. No. 6,690,029, Japanese Patent Application Laid-Open Publication No. 2004-107216, pentacene precursors described in U.S. Patent Application Publication No. 2003/136964, substituted acenes described in J. Amer. Chem. Soc., vol. 127, No. 14, 4986 and their derivatives, and the like.

Among these compounds, a preferred compound has a high solubility in an organic solvent to the extent that the compound can be processes in a solution form, forms a crystalline thin film after dried and achieves high mobility. Examples of such preferred compounds include acene compounds substituted with trialkylsilylethynyl group(s) described in J. Amer. Chem. Soc., vol. 123, p. 9482, J. Amer. Chem. Soc., vol. 130 (2008), No. 9, 2706, precursors such as pentacene precursors described in U.S. Patent Application Publication No. 2003/136964 and porphyrin precursors described in Japanese Patent Application Laid-Open Publication No. 2007-224019, and the like.

The electron-transporting material included in the electron-transporting layer in the highest constitution ratio among the electron-transporting material(s) constituting the electron-transporting layer of the present invention is a compound having Tg higher than that of the host material in the highest constitution ratio among the host material(s) constituting the light-emitting layer.

Preferable examples of the electron-transporting materials are shown below, but the present invention is not limited thereto.

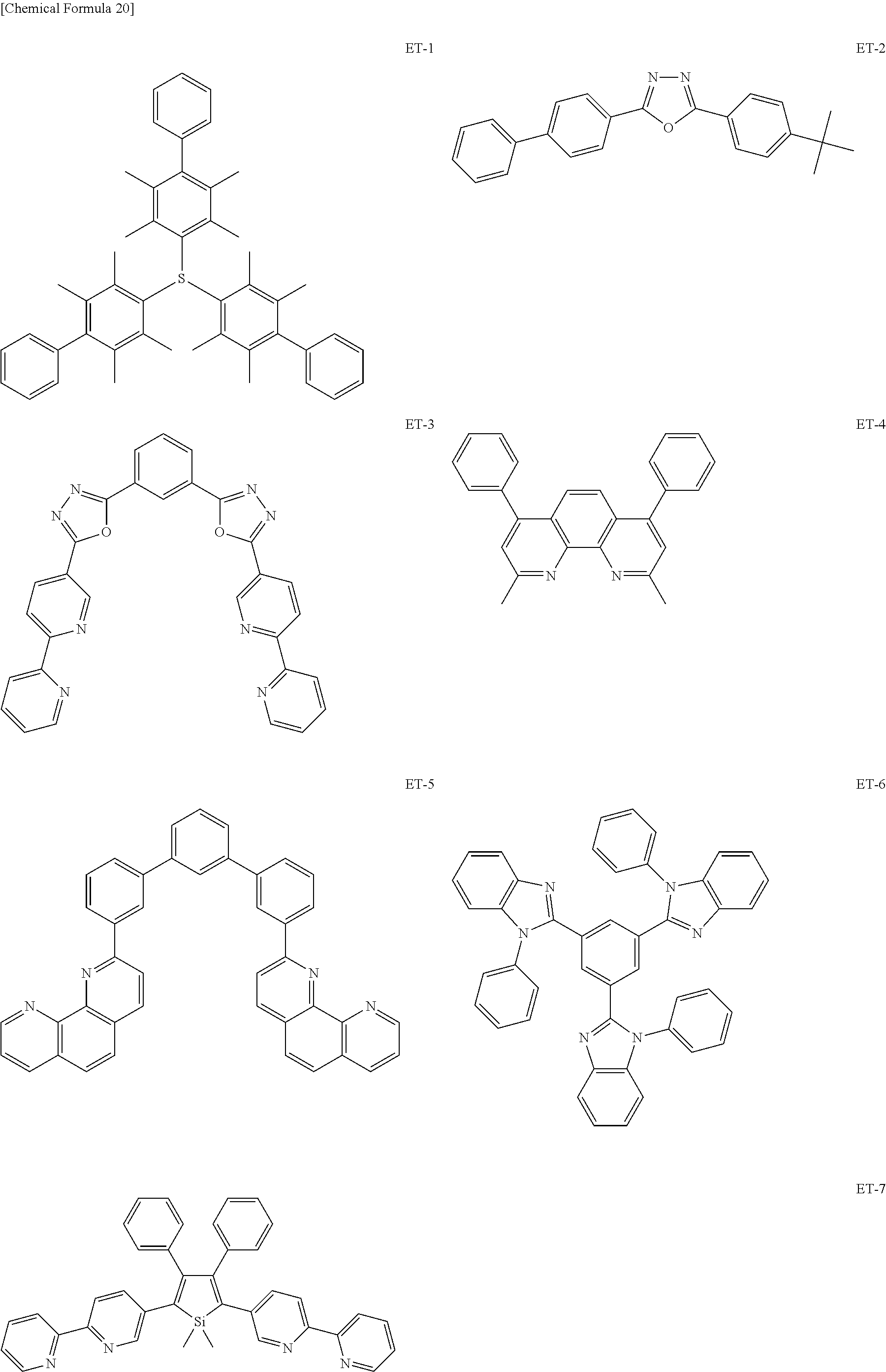

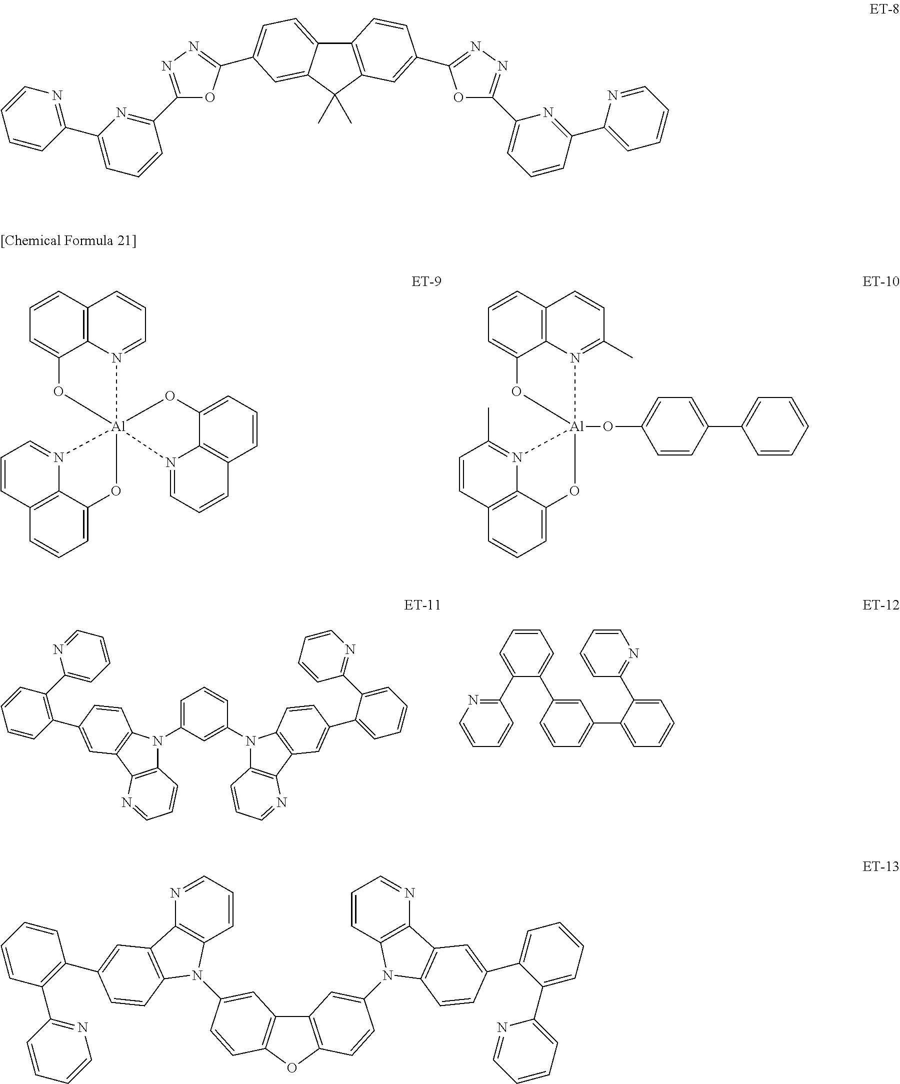

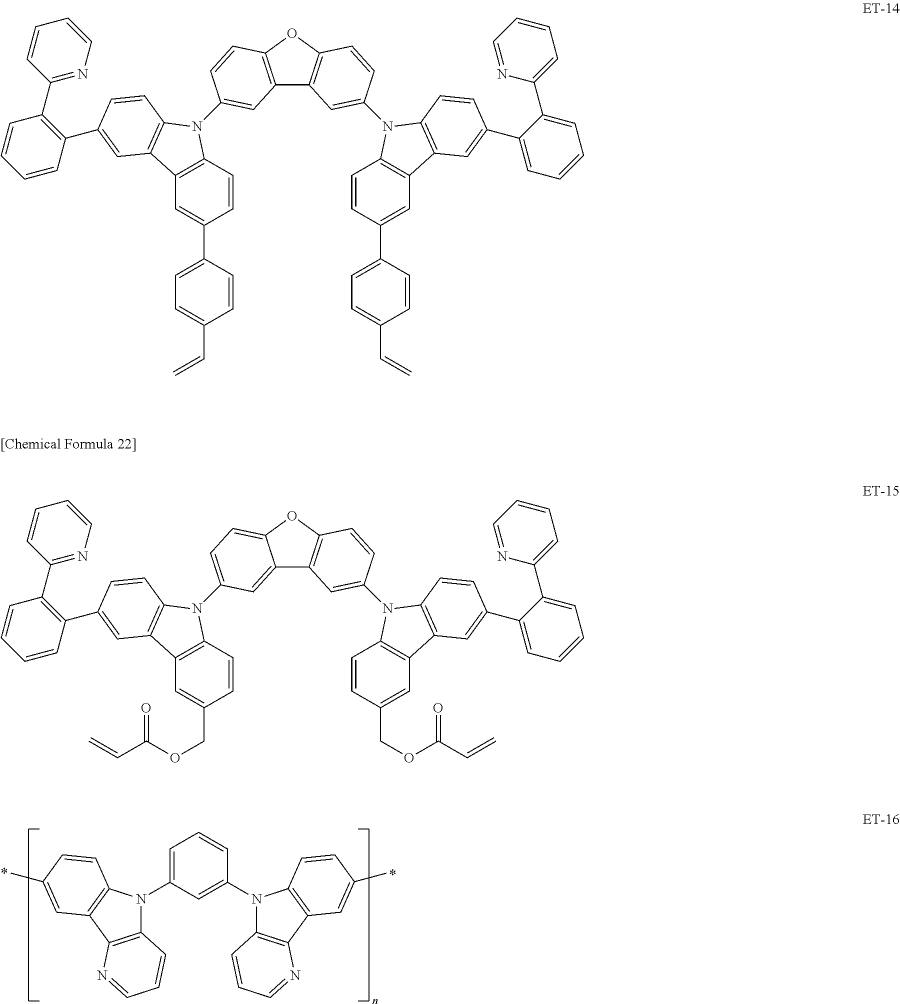

Among them, it is preferable that the electron-transporting material(s) contained in the electron-transporting layer are polymers to allow the electron-transporting layer to have Tg higher than that of the light-emitting layer.

It is more preferable that both of the hole-transporting material(s) and the electron-transporting material(s) are polymers.

<<Anode>>

The electrode material of the anode of the organic EL element is preferably a metal, alloy, or electroconductive compound having a high work function (4 eV or more) or a mixture thereof.

Specific examples of the electrode materials include metals such as Au and transparent electroconductive materials such as CuI, indium tin oxide (ITO), Sn0₂ and ZnO.

A material that is amorphous and capable of forming a transparent electroconductive layer such as IDIXO (In₂O₃—ZnO) may be used. The anode may be obtained by forming a thin film using the above electrode material(s) using a method such as deposition or sputtering, followed by patterning of the film into a desired shape by photolithography. If required precision of the pattern is not so high (about 100 μm), the pattern may be formed by depositing or sputtering the electrode material through a mask having a desired shape. Alternatively, if an appliable material such as an organic electroconductive compound is used, a wet film forming method such as printing or coating can also be used.

For extracting emitted light from the anode, the transmittance of the anode is desirably 10% or more, and the sheet resistance of the anode is preferably several hundred Ω/□ or less. The thickness of the layer is usually in a range of 10 to 1000 nm, and preferably 10 to 200 nm, while depending on the material.

<<Cathode>>

On the other hand, the electrode material of the cathode is preferably a metal having a low work function (4 eV or less) (referred to as an electron-injecting metal), alloy or electroconductive compound having a low work function (4 eV or less) or a mixture thereof. Specific examples of the electrode material include sodium, sodium-potassium alloys, magnesium, lithium, magnesium/copper mixtures, magnesium/silver mixtures, magnesium/aluminum mixtures, magnesium/indium mixtures, aluminum/aluminum oxide (Al₂O₃) mixtures, indium, lithium/aluminum mixtures and rare-earth metals.

Among them, mixtures of an electron-injecting metal and a second metal having a work function higher than that of the electron-injecting metal and being stable, such as magnesium/silver mixtures, magnesium/aluminum mixtures, magnesium/indium mixtures, aluminum/aluminum oxide (Al₂O₃) mixtures, lithium/aluminum mixtures, and aluminum are preferred from the view point of the electron-injecting property and resistance to oxidation. The cathode can be obtained by forming a thin film with the electrode material by a method such as deposition or sputtering.

The cathode preferably has a sheet resistance of several hundred Ω/□ or less and a thickness in a range of usually 10 nm to 5 μm, and preferably 50 to 200 nm. If either of the anode and the cathode of the organic EL element is transparent or translucent, the luminance is advantageously increased.

A transparent or translucent cathode can be obtained by forming a layer having a thickness of 1 to 20 nm using the metal(s) mentioned above and then providing a layer of an electroconductive transparent material (s) exemplified in the description of the anode on the metal layer. Application of this process can produce an element having a transparent anode and transparent cathode.

<<Supporting Substrate>>

The supporting substrate (also referred to as the base body, substrate, base or support) that can be used for the organic EL element of the present invention may be composed of any material such as glass or plastic and may be transparent or opaque. In the case of extracting light from the supporting substrate side, the supporting substrate is preferably transparent.

Examples of the supporting substrate preferably used include glass, quartz, and transparent resin films. A particularly preferred supporting substrate is a resin film capable of imparting flexibility to the organic EL element.

Examples of the resin film include films of polyesters such as polyethylene terephthalate (PET) and polyethylene naphthalate (PEN), polyethylene, polypropylene, cellophane, cellulose esters and their derivatives such as cellulose diacetate, cellulose triacetate, cellulose acetate butylate, cellulose acetate propionate (CAP), cellulose acetate phthalate (TAC) and cellulose nitrate, polyvinylidene chloride, polyvinyl alcohol, polyethylene vinyl alcohol, syndiotactic polystyrene, polycarbonate, norbornene resins, polymethylpentene, polyether ketones, polyimides, polyether sulfone (PES), polyphenylene sulfide, polysulfones, polyether imide, polyether ketone imide, polyamides, fluorine resins, nylon, polymethyl methacrylate, acrylics and polyarylates, and cycloolefin resins such as ARTON (trade name, manufactured by JSR Corp.) and APEL (trade name, manufactured by Mitsui Chemicals Inc.).

On the surface of the resin film, an inorganic or organic coating film or a hybrid coating film composed of the both may be formed. The coating film is preferably a barrier film having a vapor permeability of 0.01 g/(m²·24 h) or less (at 25±0.5° C. and 90±2% relative humidity (RH)) measured by a method in accordance with JIS K 7129-1992, and more preferably a high barrier film having an oxygen permeability of 10⁻³ cm³/(m²·24 h·MPa) or less and a vapor permeability of 10⁻⁵ g/(m²·24 h) or less measured by a method in accordance with JIS K 7126-1987.

The barrier film may be formed with any material that can prevent penetration of substances such as moisture and oxygen causing degradation of the element, and usable examples of the material include silicon dioxide and silicon nitride. In order to reduce the fragility of the film, a barrier film having a laminate structure composed of an inorganic layer and an organic material layer is preferable.

The inorganic layer and the organic layer may be laminated in any order, and it is preferable that the both layers are alternately laminated multiple times.

The barrier film may be formed by any method without particular limitation. For example, vacuum deposition, sputtering, reactive sputtering, molecular beam epitaxy, ionized-cluster beam deposition, ion plating, plasma polymerization, atmospheric pressure plasma polymerization, plasma CVD, laser CVD, thermal CVD, or coating may be used, and atmospheric pressure plasma polymerization as described in Japanese Patent Laid-Open Application Publication No. 2004-68143 is particularly preferable.

Examples of the opaque supporting substrate include metal plates such as aluminum and stainless steel plates; film or opaque resin substrates; and ceramic substrates.

The efficiency of light extraction of the organic EL element of the present invention at room temperature is preferably 1% or more, and more preferably 5% or more.

The quantum extraction efficiency (%) is defined as (the number of photons emitted to the exterior from the organic EL element)/(the number of electrons supplied to the organic EL element)×100.

A hue improving filter such as a color filter may be used in combination, or a color conversion filter that converts the color of light emitted by the organic EL element to many colors using a fluorescent compound may be used in combination. In the case of using the color conversion filter, the Xmax of the light emitted by the organic EL element is preferably 480 nm or less.

<<Sealing>>

Examples of the sealing ways used in the present invention include a way of bonding a sealing member to the electrode and supporting substrate with an adhesive.

The sealing member is disposed so as to cover a display area of the organic EL element and may have a concave plate shape or a flat plate shape. The transparency and the electrical insulation properties thereof are not specifically restricted.

Specific examples of the sealing member include glass plates, polymer plates and films, and metal plates and films. Examples of the glass plate include soda-lime glass, barium/strontium-containing glass, lead glass, aluminosilicate glass, borosilicate glass, barium borosilicate glass and quartz plates. Examples of the polymer plate include polycarbonate plates, acryl resin plates, polyethylene terephthalate plates, polyether sulfide plates and polysulfone plates. Examples of the metal plate include metal and alloy plates of at least one selected from the group consisting of stainless steel, iron, copper, aluminum, magnesium, nickel, zinc, chromium, titanium, molybdenum, silicon, germanium, tantalum and alloys thereof.

In the present invention, a polymer film or a metal film is preferably used from the viewpoint of reducing the thickness of the element. The polymer film preferably has an oxygen permeability of 10⁻³ cm³/(m²·24 h·MPa) or less measured by a method in accordance with JIS K 7126-1987 and a vapor permeability of 1×10⁻³ g/(m²·24 h) or less (at 25±0.5° C. and 90±2% relative humidity (RH)) measured by a method in accordance with JIS K 7129-1992.

The sealing member is formed into a concave shape by, for example, sand blasting or chemical etching.

Specific examples of the adhesive include photo-curable or thermo-curable adhesives having reactive vinyl groups such as acrylic acid oligomers and methacrylic acid oligomers, and moisture curable adhesives such as 2-cyanoacrylate.

Examples of the adhesive include an epoxy type thermally or chemically curable adhesives (two liquid mixture) such as epoxy type adhesives; hot-melt type polyamide, polyester and polyolefin adhesives; and cation curing type UV curable epoxy resin adhesives.

Since the organic EL element may be degraded by heat treatment, an adhesive that is cured in a temperature from room temperature to 80° C. is preferably used. A drying agent may be dispersed in the adhesive. Application of the adhesive to the adhering portion may be performed with a commercially available dispenser or may be performed by printing such as screen printing.

It is also preferred that an inorganic or organic layer is formed as a sealing membrane on the outer side of the electrode placed on the side facing the supporting substrate and sandwiching the organic layer therebetween so as to cover the electrode and the organic layer and to be contact with the supporting substrate. In such a case, the sealing membrane may be formed with any material that can prevent penetration of substances such as water and oxygen causing degradation of the element. Usable examples of the material include silicon oxide, silicon dioxide and silicon nitride. In order to reduce the fragility of the membrane, a sealing membrane having a laminate structure composed of an inorganic layer and an organic material layer is preferable.

The above membrane may be formed by any method without particular limitation. For example, vacuum deposition, sputtering, reactive sputtering, molecular beam epitaxy, ionized-cluster beam deposition, ion plating, plasma polymerization, atmospheric pressure plasma polymerization, plasma CVD, laser CVD, thermal CVD or coating may be employed.

In the space between the sealing member and the display area of the organic EL element, it is preferable that inactive gas such as nitrogen or argon or an inactive liquid such as fluorinated hydrocarbon or silicone oil is injected as a gas or liquid phase. The space can be a vacuum state. A hygroscopic compound may be enclosed inside.

Examples of the hygroscopic compound include metal oxides (such as sodium oxide, potassium oxide, calcium oxide, barium oxide, magnesium oxide and aluminum oxide), sulfates (such as sodium sulfate, calcium sulfate, magnesium sulfate and cobalt sulfate), metal halides (such as calcium chloride, magnesium chloride, cesium fluoride, tantalum fluoride, cerium bromide, magnesium bromide, barium iodide and magnesium iodide) and perchloric acids (such as barium perchlorate and magnesium perchlorate). As for the sulfates, metal halides and perchlorates, their anhydrides are preferably used.

<<Protective Film, Protective Plate>>

In order to increase mechanical strength of the element, a protective film or protective plate may be provided on the outer surface of the sealing membrane on the side facing the supporting substrate and sandwiching the organic layer therebetween or on the outer surface of the sealing film.

In particular, in the case of achieving sealing with the sealing membrane, since the mechanical strength of the membrane is not sufficiently high, such a protective film or plate is preferably provided. Examples of the material used for the protective film or plate include the glass plates, polymer plates and films, and metal plates and films exemplified as the materials for sealing. The polymer film is preferably used from the viewpoint of reducing the weight and the thickness.

<<Light Extraction>>

It is generally said that in an organic EL element, light is emitted in a layer whose refractive index (refractive index: about 1.7 to 2.1) is higher than that of air, and only about 15 to 20% of the light emitted in the light-emitting layer can be extracted.

This is because incident light on an interface (interface between a transparent substrate and the air) at an angle θ larger than a critical angle is totally reflected and cannot be extracted from the element or because light is totally reflected at the interface between the transparent electrode or light-emitting layer and the transparent substrate and is guided to the transparent electrode or the light-emitting layer to release the light to the direction of the element side face.

Examples of the method for improving the efficiency of light extraction include a method for preventing total reflection at the interface between the transparent substrate and the air by forming asperities on the surface of the transparent substrate (U.S. Pat. No. 4,774,435); a method for improving the efficiency by providing light-condensing property to the substrate (Japanese Patent Application Laid-Open Publication No. Sho63-314795); a method for forming a reflection surface on the side faces of the element (Japanese Patent Application Laid-Open Publication No. Heil-220394); a method for providing an anti-reflection layer by disposing a smoothing layer between the substrate and the light-emitting material, the smoothing layer having a refractive index level between those of the substrate and the light-emitting material (Japanese Patent Application Laid-Open Publication No. Sho62-172691); a method for disposing a smoothing layer between the substrate and the light-emitting body, the smoothing layer having a refractive index lower than that of the substrate (Japanese Patent Application Laid-Open Publication No. 2001-202827); and a method for providing a diffraction grating between any layers of the substrate, the transparent electrode layer, and the light-emitting layer (including on the substrate surface facing the exterior) (Japanese Patent Application Laid-Open Publication No. Hei11-283751).

In the present invention, these methods can be used for the organic EL element of the present invention. In particular, the method for disposing a smoothing layer between the substrate and the light-emitting material, the smoothing layer having a refractive index lower than that of the substrate or the method for forming a diffraction grating between any layers of the substrate, the transparent electrode layer, and the light-emitting layer (including on the substrate surface facing the exterior) may be suitably employed.

The present invention can provide an element exhibiting higher luminance or more excellent durability by combining these methods.

In the case where a medium having a low refractive index and having a thickness greater than light wavelength is provided between a transparent electrode and a transparent substrate, the extraction efficiency of light from the transparent electrode to the exterior increases with a decrease in the refractive index of the medium.

Examples of the low refractive index layer include aerogel, porous silica, magnesium fluoride, and fluorinated polymer layers. Since the refractive index of a transparent substrate is generally about 1.5 to 1.7, the refractive index of the low refractive index layer is preferably about 1.5 or less, and more preferably 1.35 or less.

The low refractive index medium desirably has a thickness twice or more a light wavelength in the medium because if the low refractive index medium has a thickness similar to the light wavelength, the electromagnetic wave exuded as an evanescent wave penetrates into the substrate, resulting in a reduction of the effect of the low refractive index layer.

The method for providing a diffraction grating into the interface at which total reflection occurs or into any medium can increase the effect of enhancing the light extraction efficiency.

In this method, a diffraction grating is provided at the interface between any layers or into any medium (in the transparent substrate or the transparent electrode) to diffract and extract the light that is emitted from the light-emitting layer but cannot exit due to, for example, total reflection occurring at the interface between the layers, taking advantages of the property of the diffraction grating that can change the direction of light to a specific direction different from that of refraction by Bragg diffraction such as primary diffraction or secondary diffraction.

The diffraction grating to be introduced desirably has a two-dimensional periodic refractive index because light generated in a light-emitting layer is emitted randomly in all directions, and thus a common one-dimensional diffraction grating having a periodic refractive index distribution only in a specific direction can diffract only the light proceeding in a specific direction and cannot greatly increase the light extraction efficiency.

The use of a diffraction grating having a two-dimensional refractive index distribution allows diffraction of light proceeding in all directions, which increases efficiency of light extraction.

The diffraction grating may be provided between any layers or into any medium (in the transparent substrate or the transparent electrode) as described above but is desirably provided near an organic light-emitting layer where light is generated.

The period of the diffraction grating is preferably about ½ to 3 times the wavelength of light in a medium.

The array of the diffraction grating is preferably a two-dimensionally repeated array such as a square lattice, a triangular lattice or a honeycomb lattice.

<<Light-Condensing Sheet>>

The organic EL element of the present invention can enhance the luminance in a specific direction by condensing light in a specific direction, for example, in the front direction with respect to the light emitting face of the element by processing to provide, for example, a micro-lens array structure on the light extraction side of the substrate or combining with a light-condensing sheet.

In an example of a micro-lens array, quadrangular pyramids having a side of 30 μm and having a vertex angle of 90 degrees are two-dimensionally arranged on the light extraction side of the substrate. The quadrangular pyramid preferably has a side of 10 to 100 μm. When the length of the side is shorter than this range, the light is colored due to the effect of diffraction, while when it is too long, the thickness is unfavorably large.

As the light-condensing sheet, one practically used in an LED backlight of a liquid crystal display device can be used. Examples of the sheet include a luminance enhancing film (BEF) produced by SUMITOMO 3M Inc. The prism sheet may have a shape, for example, triangle-shaped stripes each having a vertex angle of 90 degrees and a pitch of 50 μm, having round apexes, having randomly changed pitches, and other shapes, formed on a base material.

In order to control the emission angle of light from the light-emitting element, a light diffusion plate or film may be used in combination with the light-condensing sheet. For example, a diffusion film (Light-Up), manufactured by KIMOTO Co., Ltd., can be used.

<<Method for Producing Organic EL Element>>

As an example of the method for producing the organic EL element of the present invention, a method for producing an organic EL element composed of anode/hole-injecting layer/hole-transporting layer/light-emitting layer/electron-transporting layer/cathode will now be described.

A thin film having a thickness of 1 μm or less, preferably 10 to 200 nm, and composed of a desired electrode material, for example, the material for an anode, is formed as the anode on a suitable base by a method such as deposition or sputtering.

Subsequently, thin films including organic compounds, i.e., the hole-injecting layer, the hole-transporting layer, the light-emitting layer, the electron-transporting layer, are formed on/over the anode as the constituents of the organic EL element.

These layers are formed by vapor deposition or a wet process (such as spin coating, casting, ink jetting or printing), and preferably by a wet process. Examples of the wet process include spin coating, casting, die coating, blade coating, roll coating, ink jetting, printing, spray coating and curtain coating. In terms of forming fine and thin films with high productivity, methods highly suitable for roll-to-roll methods such as die coating, roll coating, ink jetting and spray coating are preferable. Each layer may be formed by a different method.

Defining that the total number of the layers provided between the anode and the cathode (i.e., constituent layers of the organic EL element) as 100%, it is preferable that layers whose total number is 50% or more of the total number of these layers are formed by application.

For example, in forming the above-exemplified organic EL eminent composed of anode/hole-injecting layer/hole-transporting layer/light-emitting layer/electron-transporting layer/electron-injecting layer/cathode, the total number of the layers, i.e., hole-injecting layer/hole-transporting layer/light-emitting layer/electron-transporting layer/electron-injecting layer, is 5, and thus at least three of these layers are preferably formed by application.

In the case of forming the constituent layers of the organic EL element of the present invention by application, the organic EL materials used for the application are dissolved or dispersed in liquid media, and usable examples of such a medium include ketones such as methyl ethyl ketone and cyclohexanone; aliphatic acid esters such as ethyl acetate; halogenated hydrocarbons such as dichlorobenzene; aromatic hydrocarbons such as toluene, xylene, mesitylene and cyclohexylbenzene; aliphatic hydrocarbons such as cyclohexane, decaline and dodecane; and organic solvents such as DMF and DMSO.

Dispersion can be performed by, for example, ultrasonic wave dispersion, high shearing force dispersion, or medium dispersion.

After these layers are formed, a thin film composed of the material(s) for a cathode is formed as the cathode so as to have a thickness of 1 μm or less, and preferably in a range of 50 to 200 nm by a method such as vapor deposition or sputtering. A desired organic EL element is thus produced.

Alternatively, the organic EL element can also be produced in the reverse order, i.e., in order of the cathode, the electron-injecting layer, the electron-transporting layer, the light-emitting layer, the hole-transporting layer, the hole-injecting layer and the anode.

The organic EL element of the present invention is preferably prepared by forming the above layers from the hole-injecting layer to the cathode in a single vacuuming. However, the vacuuming may be intermitted and replaced by different methods for forming layers in midstream of the vacuuming; in this case, the layers is need to be formed under a dry inert gas atmosphere, for example.

<<Application>>

The organic EL element of the present invention may be used for display devices, displays and various light sources. Examples of the light sources include lighting device (such as home lamps and in-car lamps), backlights of clocks or liquid crystal displays, billboards, traffic signals, light sources of optical storage media, light sources of electro-photocopiers, light sources of optical communication processers and light sources of optical sensors. Particularly, the organic element of the present invention may be effectively used for backlights of liquid crystal display devices and light sources for lighting.

In the organic EL element of the present invention, patterning may be conducted in forming the layer(s) using a metal mask or by inkjet printing method or the like as needed.

Patterning may be conducted only on the electrode(s), on the electrodes and the light-emitting layer, or on all of the layers of the element. In manufacturing the element, any conventionally known method may be used.

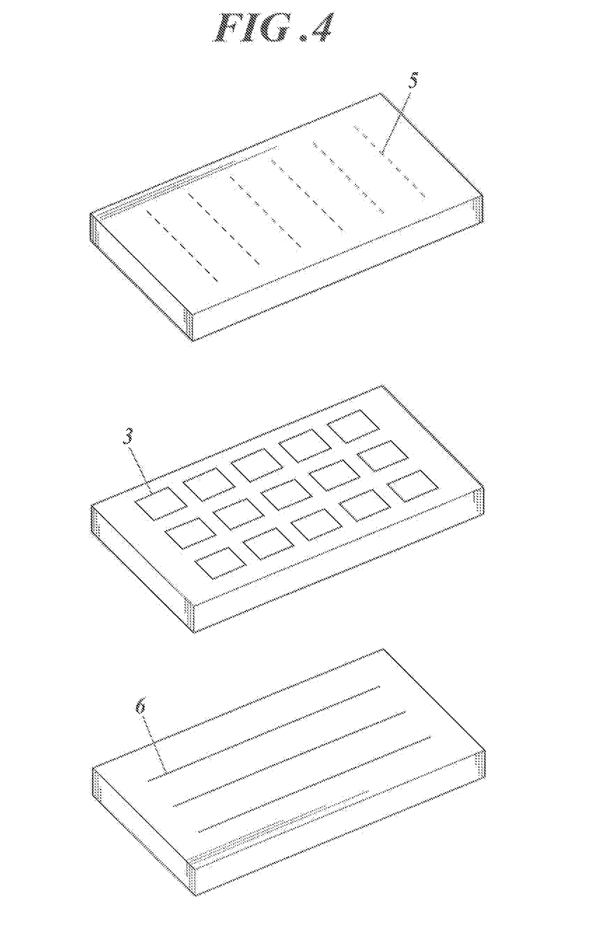

Colors of light emitted by the organic EL element of the present invention or the compounds according to the present invention are specified as the colors determined by applying the results of measurements with a spectral radiance meter CS-1000 (manufactured by Konica Minolta Sensing Co., Ltd.) to the CIE chromaticity coordinates in FIG. 4.16 on page 108 of “New Edition Color Science Handbook” (edited by The Color Science Association of Japan, University of Tokyo Press, 1985).

When the organic EL element of the present invention is a white light-emitting element, white means that when the front luminance of a 2 degree viewing angle is measured by the method described above, chromaticity in the CIE 1931 chromaticity system at 1000 cd/m² is within a region of X=0.33±0.07 and Y=0.33±0.1.

<<Display Device>>

The display device of the present invention will now be described. The display device of the present invention includes the organic EL element(s) of the present invention.

The display device of the present invention may be a monochrome or a full color display device, and a full color display device will now be described. In the case of a full color display device, the layers can be formed on each entire surface by, for example, vacuum deposition, casting, spin coating, ink jetting or printing, while a shadow mask is provided only in formation of the light-emitting layer.

When patterning is conducted only to the light-emitting layer, the patterning may be conducted by any method without particular limitation and is preferably vacuum deposition, ink jetting, spin coating or printing.

A configuration of the organic EL element(s) provided to the display device is appropriately selected from the above-exemplified configurations of the organic EL element.

The method for producing the organic EL element is as shown in the above one embodiment of the production of the organic EL element of the present invention.

When a direct current voltage, of about 2 to 40 V, is applied to the resulting full color display device defining the anode as a positive electrode and the cathode as a negative electrode, light emission can be observed. Alternatively, when a voltage is applied with reverse polarity, any current does not flow, and light is not emitted at all. When an alternating current is applied, light is emitted only in the state of the anode being positive and cathode being negative. The alternating current to be applied may have any wave form.

The full color display device can be used as a display device, a display, or various light sources. In the display device and display, full color displaying is realized by using three types of organic EL elements each of which emits blue, red or green light.

Examples of the display device and the display include televisions, personal computers, mobile devices, AV devices, teletext displays, and information displays in automobiles. In particular, the display device may be used for reproducing still images and/or moving images, and the driving system in the case of using the display device for reproducing moving images may be either a simple matrix (passive matrix) system or active matrix system.

Examples of the light sources include, but not limited to, home lamps, in-car lamps, backlights for clocks and liquid crystal displays, billboards, traffic signals, light sources of optical storage media, light sources of electro-photocopiers, light sources of optical communication processers and light sources of optical sensors.

An example of the display device including the organic EL element(s) of the present invention will now be described with reference to the drawings.

FIG. 1 is a schematic diagram illustrating an example of a display device composed of organic EL elements. The schematic diagram illustrates a display for, for example, a mobile phone to display image information through light emission by the organic EL elements.

The display 1 is composed of a display unit A including a plurality of pixels, a control unit B performing image scanning on the display unit A based on image information and so forth.

The control unit B is electrically connected to the display unit A and sends scanning signals and image data signals to the respective pixels based on externally-input image information. The pixels of each scanning line provided with the scanning signal sequentially emit light according to the image data signal, and the image information is displayed on the display unit A through image scanning.

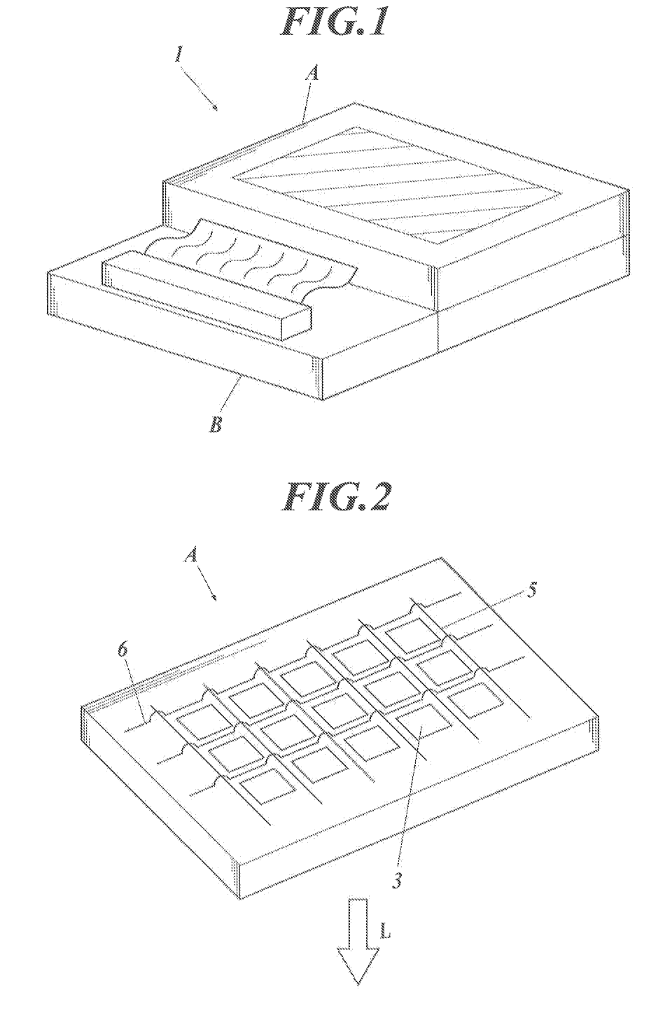

FIG. 2 is a schematic diagram of the display unit A.

The display unit A includes, for example, a line part including a plurality of scanning lines 5 and data lines 6, and a plurality of pixels 3 on a substrate. The main components of the display unit A will now be described.

In the drawing, light L emitted by the pixels 3 is extracted to the direction shown by the white arrow (downward direction).

The scanning lines 5 and the data lines 6 in the line part are made of an electrically conductive material and are disposed so as to be orthogonal to each other to form a grid pattern. The scanning lines 5 and the data lines 6 are connected to the respective pixels at the intersections (the details are not shown). A scanning signal is applied to the scanning line 5, and then the pixels 3 receive an image data signal from the data lines 6 and emit light according to the received image data.

Full color displaying is possible by appropriately apposing pixels that emit light in a red region, light in a green region or light in a blue region on a single substrate.

The light emission process of a pixel will now be described.

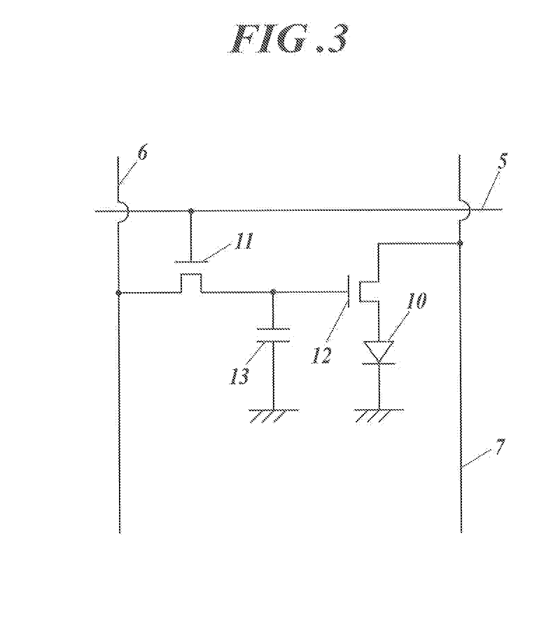

FIG. 3 is a schematic diagram of the pixel.

The pixel includes an organic EL element 10, a switching transistor 11, a driving transistor 12, a capacitor 13, etc. Full color displaying can be performed using organic EL elements 10 each of which emits red light, green light or blue light, the organic EL elements being arrayed at respective pixels on a single substrate.

In FIG. 3, an image data signal from the control unit B is applied to the drain of the switching transistor 11 via the data line 6. Then, a scanning signal from the control unit B is applied to the gate of the switching transistor 11 via the scanning line 5 to make the switching transistor 11 start driving, and the image data signal applied to the drain is transmitted to gates of the capacitor 13 and the driving transistor 12.

The capacitor 13 is charged through the transmission of the image data signal depending on the potential of the image data signal, and the driving transistor 12 starts driving. In the driving transistor 12, the drain is connected to a power source line 7, and a source is connected to the electrode of the organic EL element 10 to supply a current to the organic EL element 10 from the power source line 7 depending on the potential of the image data signal applied to the gate.

The scanning signal is transmitted to the next scanning line 5 by sequential scanning by the control unit B, and then the switching transistor 11 stops the driving. The capacitor 13 maintains the charged potential of the image data signal even after the switching transistor llstops the driving, and thus the driving state of the driving transistor 12 is maintained to continue the light emission of the organic EL element 10 until the next scanning signal is applied. The driving transistor 12 is driven according to the potential of the subsequent image data signal in synchronization with the subsequent scanning signal applied by sequential scanning. Then the organic EL element 10 emits light.

That is, light emission by the organic EL element 10 is realized by providing the switching transistor 11 and the driving transistor 12 serving as active elements to the organic EL element 10 of each pixel and by allowing the respective organic EL elements 10 of the pixels 3 to emit light. Such a light emitting process is called an active matrix system.

Light emitted by the organic EL element 10 may have multiple gradations according to multi-valued image data signals having different gradation electric potentials, or light emission by the organic EL element 10 may be turning on and off of light of a predetermined intensity according to a binary image data signal. The electric potential of the capacitor 13 may be maintained until the subsequent scanning signal is applied, or may be discharged immediately before the subsequent scanning signal is applied.

In the present invention, the light emission may be driven by a passive matrix system as well as the active matrix system described above. In the passive matrix system, light is emitted by the organic EL element in response to the data signal only during application of the scanning signals.

FIG. 4 illustrates a schematic diagram of a passive-matrix display device. In FIG. 4, pixels are provided between the scanning lines 5 and the image data lines 6 that are orthogonal to each other across the pixel 3 to form a grid pattern.

When a scanning signal is applied to a scanning line 5 by a sequential scanning, the pixel 3 connected to the scanning line 5 to which the scanning signal is applied emits light in accordance with the image data signal.

The passive matrix system does not have any active element in the pixels 3, resulting in a reduction in manufacturing cost.

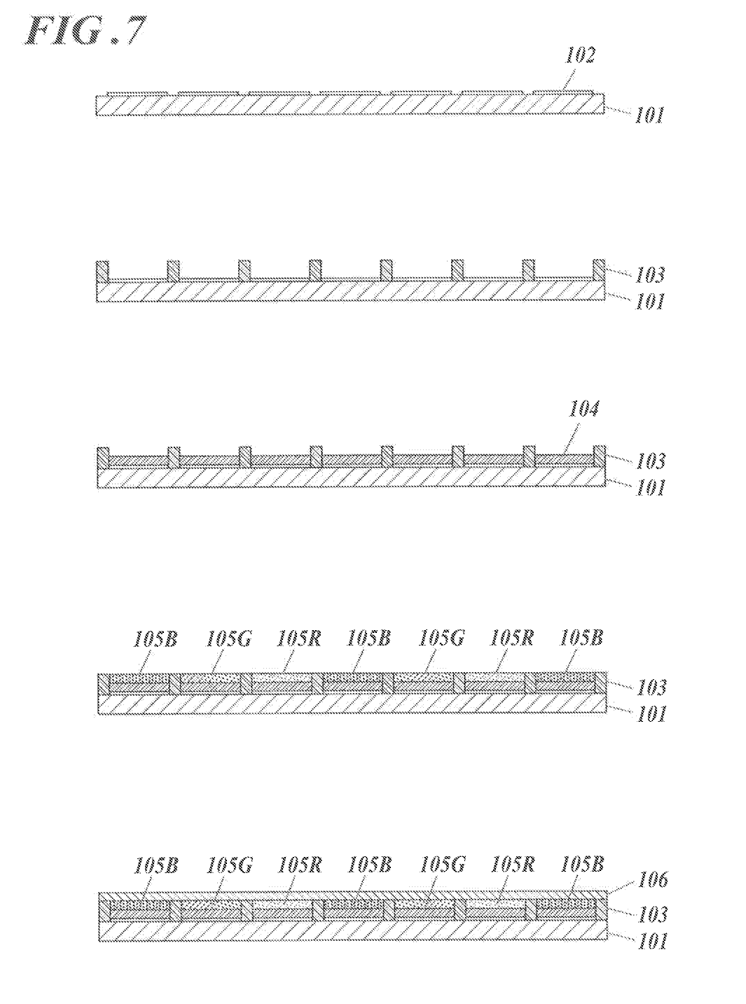

FIG. 7 illustrates a schematic diagram of the configuration of a full color organic EL display device. A glass substrate 101 provided with ITO electrodes 102 thereon is subjected to patterning to obtain the anode. Then, barrier walls 103 are formed on the resulting substrate. In the spaces defined by the barrier walls, the hole-transporting layer compound is injected onto the ITO electrodes and then dried to form the hole-injecting layers 104. On each of these hole-injecting layers, a blue light-emitting layer compound, a green light-emitting layer compound or a red light-emitting layer compound is injected. Light-emitting layers 105B, light-emitting layers 105G and light-emitting layer 105R are thus formed. Then a cathode 106 is formed so as to cover the light-emitting layers 105B, the light-emitting layers 105G and the light-emitting layers 105R by vacuum deposition. An organic EL element is thus produced.

<<Lighting Device>>

A lighting device of the present invention will be described. The lighting device of the present invention includes the organic EL element(s) described above. The organic EL element of the present invention may have a resonator structure. Such an organic EL element having a resonator structure can be applied to, but not limited to, light sources for optical memory media, light sources for electro-photocopiers, light sources of optical communication processers and light sources of optical sensors, for example. Alternatively, the organic EL element of the present invention may be used for the above applications by employing laser oscillation.

The organic EL element of the present invention may be used as a lamp such as a lighting source or an exposure light source or may be used as a projector for projecting images or a display device (display) for direct view of still or moving images.

A driving system of the display device used for playback of moving images may be either a simple matrix (passive matrix) system or an active matrix system. Furthermore, a full color display device can be produced by employing two or more types of organic EL elements of the present invention that emit lights of different colors. The organic EL material of the present invention can be applied to an organic EL element emitting substantially white light as a lighting device. The white light is generated by mixing lights of different colors simultaneously emitted by a plurality of light-emitting materials. The combination of colors of the emitted lights may be a combination containing light of three maximum wavelengths of three primary colors of blue, green and red or a combination containing light of two maximum wavelengths using a relationship of complimentary colors such as blue and yellow or blue-green and orange.

To obtain a plurality of colors, the combination of light-emitting materials may be either a combination of a plurality of phosphorescence or fluorescence emitting materials or a combination of a fluorescent or phosphorescent material and a coloring material that emits light as excited light using the light from the light-emitting material. However, in the white organic EL element of the present invention, it is sufficient to combine and mix only a plurality of light-emitting dopants for this purpose.

It is sufficient that during formation of the light-emitting layer, the hole-transporting layer or the electron-transporting layer, a mask can be simply arranged to conduct patterning via the arranged mask. The other layers are common and do not require any patterning with a mask or the like, and for example, an electrode film can be formed on the entire upper surface by, for example, vacuum deposition, casting, spin coating, ink jetting or printing, and thus productivity is also enhanced.

According to this method, the element itself emits white light, unlike a white organic EL device including light-emitting elements emitting lights of different colors apposed in an array form.

Any light-emitting material(s) can be used without particular limitation for a light-emitting layer. For example, in a backlight of a liquid crystal display element, white light may be made by appropriately selecting and combining the metal complex(es) of the present invention or a known light-emitting material(s) so as to match with the wavelength range corresponding to color filter (CF) characteristics.

<<Embodiment of Lighting Device of the Present Invention>>

An embodiment of the lighting device including the organic EL element(s) of the present invention will now be described.

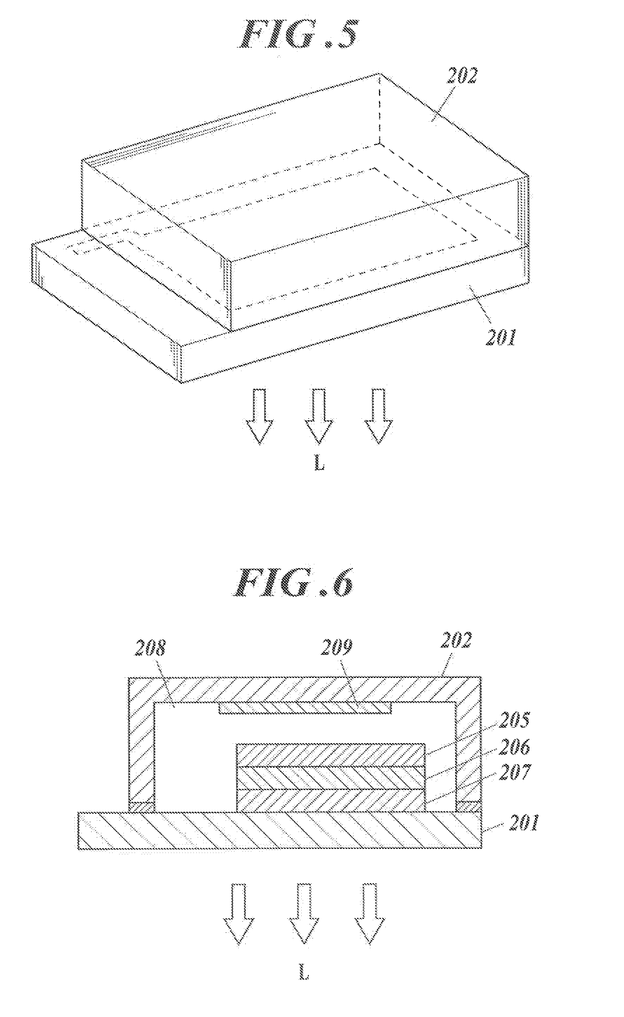

A non-light-emitting face of the organic EL element of the present invention is covered with a glass case, and a glass substrate having a thickness of 300 μm is used as a sealing substrate. As a sealing material, an epoxy based photo-curable adhesive (LUXTRACK LC0629B manufactured by Toagosei Co., Ltd.) is applied to the periphery, and the glass case is placed from above the cathode and is adhered to the transparent supporting substrate, followed by curing the adhesive by irradiation with UV light from the side of the glass substrate for sealing. Thus, a lighting device as shown in FIGS. 5 and 6 can be formed.

FIG. 5 is a schematic diagram illustrating the lighting device. The organic EL element of the present invention is covered with a glass cover 202 (sealing with the glass cover is performed in a glove box under a nitrogen atmosphere (an atmosphere of high purity nitrogen gas having a purity of at least 99.999%) for preventing the organic EL element 201 from being contact with the air).

FIG. 6 is a cross-sectional view of the lighting device. In FIG. 6, the reference numeral 205 denotes a cathode, 206 denotes organic EL layers, 207 denotes a transparent electrode and 2013 denotes a glass substrate. The inside of the glass cover 202 is filled with nitrogen gas 208 and is provided with a water absorbent 209.

### EXAMPLE

The present invention will now be described with reference to Examples, but the present invention is not limited thereto. In Examples, “part (s)” and “%” indicate “part (s) by mass” and “% by mass”, respectively, unless stated otherwise.

### Example 1

### Production of Organic EL Element

(Production of Organic EL Element 1-1)

A substrate (NA-45, manufactured by NH Techno Glass Corp.), prepared by forming a film of ITO (indium tin oxide) having a thickness of 100 nm on a glass substrate of 100×100×1.1 mm, was patterned to form an anode. This transparent supporting substrate provided with the ITO transparent electrode was cleaned with ultrasonic waves in isopropyl alcohol, dried with dry nitrogen gas, and subjected to UV ozone washing for 5 minutes. On this substrate, a film was formed with a 70% solution of poly(3,4-ethylenedioxythiophene)-polystylene sulfonate (abbreviated as PEDOT/PSS, P AI 4083 manufactured by Bayer AG) in pure water by spin coating at 3000 rpm for 30 seconds, followed by drying at 200° C. for an hour. A first hole-transporting layer having a thickness of 30 nm was thus formed.

The resulting substrate on which the first hole-transporting layer had been formed was fixed on a substrate holder of a commercially available vacuum deposition device, and organic EL materials described below were each put in a molybdenum or tantalum resistive heating boat. Then, the vacuum chamber was depressurized to 4×10⁻⁴Pa, and the heating boat in which HT-1 (hole-transporting material) was electrified to deposit HT-1 at a deposition rate of 0.1 nm/sec. A second hole-transporting layer having a thickness of 20 nm was thus formed.

Subsequently, the heating boat in which OC-3 (host material) was put and the heating boat in which PD-1 (phosphorescent dopant) was put were electrified to co-deposit them at a deposition rate of 0.1 nm/sec and 0.006 nm/sec, respectively, on the second hole-transporting layer. A light-emitting layer having a thickness of 40 nm was thus formed.

Then, ET-4 (electron-transporting material) was deposited on the light-emitting layer at a deposition rate of 0.1 nm/sec to form a first electron-transporting layer having a thickness of 20 nm. Subsequently, the heating boat in which tris(8-quinolinato)aluminum (Alq₃) was put was electrified to deposit Alq₃ on the first electron-transporting layer at a deposition rate of 0.1 nm/sec to form a second electron-transporting layer having a thickness of 20 nm.

Then, lithium fluoride was deposited to form a cathode buffer layer having a thickness of 0.5 nm, and aluminum was deposited to form a cathode having a thickness of 110 nm. An organic EL element 1-1 was thus produced. The temperature of the substrate during the above depositions was room temperature.

(Production of Organic EL Elements 1-2 to 1-8)

Organic EL elements 1-2 to 1-8 were each produced by the same way as the organic EL element 1-1 was prepared except that materials constituting the layers were changed as shown in Table 1 through vacuum deposition, whereas HT-19 (hole-transporting material), polyvinylcarbazole (PVK) and ET-16 (electron-transporting material) were applied to form the layers. Conditions for their application were described below.

Condition for Forming Second Hole-Transporting Layer Using HT-19:

0.5% dichlorobenzene solution of H-19 was prepared, and then a film was formed using this solution by spin coating at 1500 rpm for 30 seconds, followed by drying at 200° C. for an hour. A second hole-transporting layer having a thickness of 30 nm was thus formed. The weight average molecular weight of HT-19 measured as described below was 70,000.

Condition for Forming Light-Emitting Layer Using PVK:

10 mg of polyviylcarbazole (PVK) and 0.3 mg of PD-1 were dissolved in 3 ml of toluene. A film was then formed using this solution by spin coating at 100 rpm for 30 seconds, followed by drying at 120° C. for an hour. A light-emitting layer having a thickness of 40 nm was thus formed. The weight average molecular weight of PVK measured as described below was 120,000.

Condition for Forming First Electron-Transporting Layer Using ET-16:

0.2% toluene:hexafluoroisopropanol (HFIP) (5:95) of ET-16 was prepared. A film was then formed using this solution by spin coating at 1500 rpm for 30 seconds, followed by drying at 120° C. for an hour. A first electron-transporting layer having a thickness of 20 nm was thus formed. The weight average molecular weight of ET-16 measured as described below was 28,000.

(Method for Measuring Weight Average Molecular Weight)

1 ml of THF (degassed) was used for 1 mg of the material to be measured, and stirring was conducted at room temperature using a magnetic stirrer for sufficient dissolution. Filtration was then conducted using a membrane filter having a pore size of 0.45 to 0.50 μm, and the resulting solution is injected into a Gel Permeation Chromatography (GPC) device.

In the measurement by GPC, the column was stabilized at 40° C., and tetrahydrofuran (THF) was flown into the column.

(Condition for Measurement)

Device: TOSOH High-speed GPC apparatus HLC-8220GPC

Column: TOSOH TSKgel Super HM-M

Flow Rate of Eluate: 0.6 ml/min

Material Concentration: 0.1 part by mass

Material Amount: 100 ml

Calibration Curve It was drawn using standard polystylene; 13 samples with Mw ranging from 1000000 to 500 of STK standard polystylene (manufactured by TOSOH CORPORATION) were used to draw a calibration curve (or a standard curve) to be used for calculating molecular weights. These 13 samples were selected so as to obtain almost equal intervals between their points.

TABLE 1

| ORGANIC | | LIGHT-EMITTING LAYER | | | |
|---|---|---|---|---|---|
| EL | | HOST | LIGHT-EMITTING | | |
| ELEMENT | *1 | MATERIAL | MATERIAL | *2 | NOTE |
| 1-1 | HT-1 | OC-3 | PD-1 | ET-4 | COMPARATIVE EXAMPLE |
| 1-2 | HT-1 | OC-3 | PD-1 | ET-16 | COMPARATIVE EXAMPLE |
| 1-3 | HT-19 | OC-3 | PD-1 | ET-4 | COMPARATIVE EXAMPLE |
| 1-4 | HT-19 | PVK | PD-1 | ET-16 | PRESENT INVENTION |
| 1-5 | HT-2 | OC-3 | PD-1 | ET-3 | PRESENT INVENTION |
| 1-6 | HT-19 | OC-3 | PD-1 | ET-3 | PRESENT INVENTION |
| 1-7 | HT-2 | OC-3 | PD-1 | ET-16 | PRESENT INVENTION |
| 1-8 | HT-19 | OC-3 | PD-1 | ET-16 | PRESENT INVENTION |

*1: SECOND HOLE-TRANSPORTING LAYER HOLE-TRANSPORTING MATERIAL
*2: FIRST ELECTRON-TRANSPORTING LAYER ELECTRON-TRANSPORTING MATERIAL

The glass transition temperatures of the used materials are shown in Tables 2 to 4. The glass transition temperatures were measured using a differential scanning calorimeter DSC-7 (manufactured by PerkinElmer Co., Ltd.) or a thermal analysis controller TAC7/DX (manufactured by PerkinElmer Co., Ltd.).

TABLE 2

| COMPOUND | Tg (° C.) |
|---|---|
| HT-1 | 60 |
| HT-2 | 96 |
| HT-31 | 115 |
| HT-32 | 121 |
| HT-19 | 135 |

TABLE 3

| COMPOUND | Tg (° C.) |
|---|---|
| OC-7 | 65 |
| OC-3 | 85 |
| OC-13 | 120 |
| PVK | 131 |
| OC-23 | 132 |

TABLE 4

| COMPOUND | Tg (° C.) |
|---|---|
| ET-4 | 83 |
| ET-3 | 102 |
| ET-6 | 122 |
| ET-8 | 134 |
| ET-16 | 138 |

### Evaluation of Organic EL Element

The organic EL elements 1-1 to 1-8 produced as described above were evaluated for the following points. Results are shown in Table 5.

In the evaluation of the produced organic EL elements, a non-light-emitting face of each produced organic EL element was covered with a glass case, and a glass substrate having a thickness of 300 μm was used as a sealing substrate. As a sealing material, an epoxy based photo-curable adhesive (LUXTRACK LC0629B manufactured by Toagosei Co., Ltd.) was applied to the periphery, and the glass case was then from placed above the cathode and was adhered to the transparent supporting substrate, followed by curing the adhesive by irradiation with UV light from the side of the glass substrate for sealing. Lighting devices as shown in FIGS. 5 and 6 were thus produced and then evaluated.

(External Extraction Quantum Efficiency)

External extraction quantum efficiencies (%) of the produced organic EL elements to which a constant current of 2.5 mA/cm² was applied were measured with a spectroradiometer CS-1000 (manufactured by Konica Minolta Sensing Inc.). The external extraction quantum efficiencies of the organic EL elements are described in relative values defining the external extraction quantum efficiency of the organic EL element 1-1 is 100.

(Change in Voltage in Constant Current Driving)

Changes in voltage in constant current driving of the produced organic EL elements to which a constant current of 2.5 mA/cm² was applied were measured under a dry nitrogen gas atmosphere. Defining that the voltage at the initial luminance under the condition for measuring light-emitting life described later was (DV₀), the voltage at the time when the luminance decreased by 30% with respect to the initial luminance was (DV₇₀) and the voltage at the time when the luminance decreased by 50% (i.e., by half) with respect to the initial luminance was (DV₅₀), it is defined that Δ₁ is equal to (DV₇₀) minus (DV₅₀) and Δ₂ is equal to (DV₅₀) minus (DV₀). Δ₁ and Δ₂ can indicate the changes with time in driving voltage, and are described in relative values defining that Δ₁ and Δ₂ of the organic EL element 1-1 are 100.

(Light Emission Life)

The organic EL element was driven with a constant current of 2.5 mA/cm² at 23° C. under a dry nitrogen gas atmosphere. The time period until the luminance decreased by a half of the luminance immediately after the start of the emission (initial luminance) was measured. This time period, i.e., half-life (τ0.5), was used as an indicator of the life. The luminance was measured with a spectroradiometer CS-1000 (manufactured by Konica Minolta Sensing Inc.). Results are described in relative values defining that the value of the organic EL element 1-1 is 100.

TABLE 5

| | | VOLTAGE | | | |
|---|---|---|---|---|---|
| | | CHANGE IN | | | |
| | EXTERNAL | CONSTANT | | | |
| ORGANIC | EXTRACTION | CURRENT | | LIGHT- | |
| EL | QUANTUM | DRIVING | | EMITTING | |
| ELEMENT | EFFICIENCY | Δ₁ | Δ₂ | LIFE | NOTE |
| 1-1 | 100 | 100 | 100 | 100 | COMPARATIVE EXAMPLE |
| 1-2 | 103 | 105 | 103 | 105 | COMPARATIVE EXAMPLE |
| 1-3 | 102 | 98 | 100 | 95 | COMPARATIVE EXAMPLE |
| 1-4 | 105 | 95 | 98 | 110 | PRESENT INVENTION |
| 1-5 | 108 | 90 | 90 | 300 | PRESENT INVENTION |
| 1-6 | 112 | 61 | 55 | 920 | PRESENT INVENTION |
| 1-7 | 113 | 65 | 55 | 880 | PRESENT INVENTION |
| 1-8 | 116 | 54 | 45 | 1200 | PRESENT INVENTION |

As evident from the above results, the relation between Tgs of the three layers including the layers each adjacent to the light-emitting layer is important, whereas it has been commonly understood that the higher Tg is better. When the relation of Tgs of the light-emitting layer and its adjacent layers satisfies the relation as defined by the present invention, carrier-trapping function of the light-emitting layer is facilitated and thus exciton-trapping function can be exerted to suppress undesirable deterioration around the interfaces. The change in voltage in constant current driving as well as the external quantum efficiency are significantly improved. As a result, a light-emitting life is greatly improved.

### Example 2

### Production of Organic EL Element

(Production of Organic EL Elements 2-1 to 2-4)

Organic EL elements 2-1 to 2-4 were produced by the same way as the example 1-1 except that materials for the layers were changed as shown in Table 6. The condition for forming the layers by application is same as that of Example 1.

TABLE 6

| ORGANIC | | LIGHT-EMITTING LAYER | | | |
|---|---|---|---|---|---|
| EL | | HOST | LIGHT-EMITTING | | |
| ELEMENT | *1 | MATERIAL | MATERIAL | *2 | NOTE |
| 2-1 | HT-1 | OC-7 | PD-13 | ET-4 | COMPARATIVE EXAMPLE |
| 2-2 | HT-19 | OC-7 | PD-13 | HT-16 | PRESENT INVENTION |
| 2-3 | HT-19 | OC-13 | PD-13 | HT-16 | PRESENT INVENTION |
| 2-4 | HT-19 | OC-23 | PD-13 | HT-16 | PRESENT INVENTION |

*1: SECOND HOLE-TRANSPORTING LAYER HOLE-TRANSPORTING MATERIAL
*2: FIRST ELECTRON-TRANSPORTING LAYER ELECTRON-TRANSPORTING MATERIAL

### Evaluation of Organic EL Element

The produced organic EL elements 2-1 to 2-4 were evaluated by the same ways as those were evaluated in Example 1. Results are shown in Table 7.

TABLE 7

| | | VOLTAGE | | | |
|---|---|---|---|---|---|
| | | CHANGE IN | | | |
| | EXTERNAL | CONSTANT | | | |
| ORGANIC | EXTRACTION | CURRENT | | LIGHT- | |
| EL | QUANTUM | DRIVING | | EMITTING | |
| ELEMENT | EFFICIENCY | Δ₁ | Δ₂ | LIFE | NOTE |
| 2-1 | 100 | 100 | 100 | 100 | COMPARATIVE EXAMPLE |
| 2-2 | 110 | 65 | 55 | 550 | PRESENT INVENTION |
| 2-3 | 124 | 50 | 42 | 1500 | PRESENT INVENTION |
| 2-4 | 108 | 63 | 58 | 900 | PRESENT INVENTION |

The results from Example 2 also demonstrate that the relation between Tgs of the three layers including the layers each adjacent to the light-emitting layer is evidently important. In addition, it is revealed that there can be an appropriate Tg of the host material. This is because the lower Tg or the larger difference between Tgs of the two adjacent layers is preferable for fully achieving carrier-trapping ability, which is the object of the present invention, whereas the host material desirably has the higher Tg in terms of stability of the layer against heat and time, as it has been understood. Therefore, the Tg of the host material of the present invention is preferably 70° C. or more and 130° C. or less.

### Example 3

### Production of Full Color Display Device

(Blue Light-Emitting Organic EL Element)

The organic EL element 2-3 produced in Example 2 was used.

(Green Light-Emitting Organic EL Element)

The organic EL element 1-8 produced in Example 1 was used.

(Red Light-Emitting Organic EL Element)

An organic EL element 1-8R was used, the organic EL element 1-8R being produced by the same way as the organic EL element 1-8 was produced except that PD-1 used in the light-emitting layer was replaced by PD-10.

The produced organic EL elements above each emitted blue, green or red light, and it was proved that these organic EL elements can be used for a full color display device.

### Example 4

### Production of White Light-Emitting Display Device

A white light-emitting organic EL element 2-3W was produced by the same way as the organic EL element 2-3 was prepared except that PD-13 was replaced by a composite of three compounds, namely, PD-1, PD-13 and PD-10. A non-light-emitting face of the produced organic EL element 2-3W was covered with a glass cover, and a lighting device was then produced. The lighting device can be used as a thin white light-emitting lighting device with high light emission efficiency and a long light-emitting life.

### INDUSTRIAL APPLICABILITY

A full color display device can be obtained through arranging the blue light-emitting organic EL element(s), the green light-emitting organic EL element(s) and the red light-emitting organic EL element(s) in a certain pattern. In addition, a white light-emitting organic EL element can be obtained by using phosphorescent organic metal complex compounds that emit lights of different colors in combination in the element. Such a white light-emitting organic EL element can be used for a backlight of a display device and a liquid crystal display device.

### DESCRIPTION OF REFERENCE NUMERAL

1 Display
3 Pixel
5 Scanning line
6 Data line
7 Power source line
10 Organic EL element
11 Switching transistor
12 Driving transistor
13 Capacitor
A Display unit
B Control unit
101 Glass substrate
102 ITO transparent electrode
103 Barrier wall
104 Hole-injecting layer
105B, 105G, 105R Light-emitting layer
106 Cathode
201 Glass substrate
207 Glass substrate with transparent electrode
206 Organic EL layer
205 Cathode
202 Glass cover
208 Nitrogen gas
209 Water absorbent
L Light

1. An organic electroluminescent element comprising a plurality of organic compound layers including a hole-transporting layer, a light-emitting layer and an electron-transporting layer, the plurality of the organic compound layers being provided between an anode and a cathode, wherein
(1) the hole-transporting layer and the electron-transporting layer are each adjacent to the light-emitting layer,
(2) Tg(HT)>Tg(EM) where a glass transition temperature (Tg) of a hole-transporting material constituting the hole-transporting layer in a highest constitution ratio among a hole-transporting material(s) constituting the hole-transporting layer is defined as Tg(HT) and a glass transition temperature (Tg) of a host material constituting the light-emitting layer in a highest constitution ratio among a host material(s) constituting the light-emitting layer is defined as Tg(EM),
(3) Tg(ET)>Tg(EM) where a glass transition temperature (Tg) of an electron-transporting material constituting the electron-transporting layer in a highest constitution ratio among an electron-transporting material(s) constituting the electron-transporting layer is defined as Tg(HT) and the glass transition temperature (Tg) of the host material constituting the light-emitting layer in the highest constitution ratio among the host material(s) constituting the light-emitting layer is defined as Tg(EM), and
(4) a phosphorescent organic metal complex compound is contained as a material constituting the light-emitting layer.

2. The organic electroluminescent element of claim 1, wherein
the glass transition temperature Tg of the host material contained in the light-emitting layer ranges from 70 to 130° C.

3. The organic electroluminescent element of claim 1, wherein
the hole-transporting material contained in the hole-transporting layer is a polymer.

4. The organic electroluminescent element of claim 1, wherein
the electron-transporting material contained in the electron-transporting layer is a polymer.

5. The organic electroluminescent element of claim 1, wherein
both of the hole-transporting material contained in the hole-transporting layer and the electron-transporting material contained in the electron-transporting layer are polymers.

6. The organic electroluminescent element of claim 1, wherein
at least one of the phosphorescent organic metal complex compound(s) is a compound represented by a following formula (1): 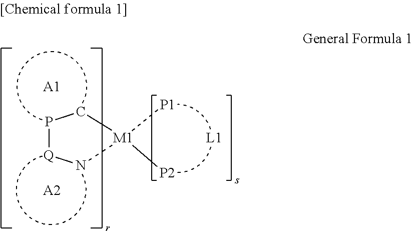
wherein P and Q each represent a carbon atom or a nitrogen atom; A1 represents a group of atoms forming an aromatic hydrocarbon ring or an aromatic hetero ring together with P—C; A2 represents a group of atoms forming an aromatic hetero ring together with Q-N; P1-L1-P2 represents a bidentate ligand; P1 and P2 each independently represent a carbon atom, a nitrogen atom or an oxygen atom; L1 represents a group of atoms forming the bidentate ligand together with P1 and P2; r represents an integer from 1 to 3; s represents an integer from 0 to 2; r plus equals 2 or 3; and M represents a metal element of Group 8 to 10 of the periodic table.

7. The organic electroluminescent element of claim 1, wherein
the organic electroluminescent element emits white light.

8. A lighting device comprising the organic electroluminescent element of claim 1.

9. A display device comprising the organic electroluminescent element of claim 1.
